(19) United States
(12) Patent Application Publication
(10) Pub. No.: US 2008/0116671 A1
(43) Pub. Date: May 22, 2008

(54) Method of Manufacturing a Ignition Device and a Semiconductor Device

(76) Inventor: Yasushi Takahashi, Takasaki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 10/559,658

(22) PCT Filed: Dec. 6, 2004
(86) PCT No.: PCT/JP04/18168

§ 371 Date: Dec. 5, 2005

(51) Int. Cl. B60R 21/013; H01L 25/00

(52) U.S. Cl. 280/735; 326/47; 327/524

(57) ABSTRACT

A semiconductor device has the package structure which used the lead frame, a communication device (semiconductor chip) is arranged to the main surface side of a supporting body, and the condenser for firing is arranged to the back side of the opposite side to the main surface of said supporting body. By having such structure, a miniaturization, the reduction of a manufacturing cost, and high reliability of a semiconductor device and an ignition device can be aimed at.

### INCORPORATION BY REFERENCE

The present application claims priority from PCT application PCT/JP2004/018168 filed on Dec. 6, 2004, the content of which is hereby incorporated by reference into this application.

### TECHNICAL FIELD

The present invention relates to an ignition device and a semiconductor device, and particularly relates to the ignition device used for the airbag system of a bus-connection method, and the semiconductor device built in it.

### BACKGROUND ART

An air bag device mounted in an automobile expands an air bag with the high pressure gas which occurs by burning of propellant. An ignition device (squib) for lighting said propellant is formed in the air bag device. The ignition device connected to the ignition control device into which the acceleration signal accompanying the collision of a car is inputted lights said propellant by energizing for the firing element and making it generate heat, and expands an air bag.

By the way, in an automobile in recent years, the number of the circuits in a firing circuit control device must be increased corresponding to the number of each air bag devices in connection with the multi-channel formation in which many air bag devices, such as a steering wheel, a dashboard, a side part of a seat, and a side part of a roof, are mounted. Whenever air bag devices increase in number, even if it is the same model, an ignition control device must be remade. So, in both case, a manufacturing cost increases. If an ignition control device and said each air bag device are connected with a wire harness for exclusive use, respectively, the length of a harness will become huge and reservation of the space of arrangement will become difficult. Since the weight increases only the number of wire harnesses, for example with 70-100 kg, the weight saving of an airbag system is difficult.

Then, the airbag system of the bus-connection method which supplies the electrical signal for operating only the ignition device of a predetermined air bag device among a plurality of air bag devices while connecting a plurality of air bag devices to the common bus which extends from an ignition control device and supplying the electrical energy for firing to the ignition device of each air bag device from said ignition control device is disclosed by Japanese Unexamined Patent Publication No. 2004-203294 (Patent Reference 1), for example. The technology of constituting communication/firing circuit which communicates between ignition control devices and outputs an ignition signal, and the firing element which operates with the ignition signal which this communication/firing circuit outputs, and lights propellant from same package, and aiming at the miniaturization of an ignition device is also disclosed by the same gazette.

In Japanese Unexamined Patent Publication No. 2003-252168 (Patent Reference 2), the ignition device having the condenser which supplies the current for operating an air bag device is disclosed, and the structure which supplies the current for condensers (charging signal) via the common bus which extends from an ignition control device is disclosed.

[Patent Reference 1] Japanese Unexamined Patent Publication No. 2004-203294

[Patent Reference 2] Japanese Unexamined Patent Publication No. 2003-252168

### DISCLOSURE OF THE INVENTION

The present inventor found out that the following problems occurred, as a result of considering the miniaturization of the ignition device used for an airbag system.

Since the package for firing and the input/output terminal part (pin) are unifying, the ignition device of above-mentioned Patent Reference 1 is lacking in the workability of a characteristic check, or assembly nature, and difficult to correspond for different pinout.

In above-mentioned Patent Reference 2, it is not disclosed in detail about arrangement of the condenser built in an ignition device, and the structure which builds in a condenser.

As for communication/firing circuit which communicates between ignition control devices and outputs an ignition signal, since it is mounted on the substrate, cost reduction of an ignition device is difficult, and since the wiring layer for acquiring the ignition signal from an ignition control device is also required when forming an ignition device on a substrate, a miniaturization is also difficult.

Also in reliability, the adhesion of a substrate and sealing resin is weak, and it is easy to generate peeling by the stress of thermal stress by a temperature cycle.

In order to reduce or cancel the above-mentioned concern, it becomes an important problem how it deals with a miniaturization and reduction of a manufacturing cost, and a reliable ignition device is obtained.

A purpose of the present invention is to offer the technology which can aim at the miniaturization of a semiconductor device.

Another purpose of the present invention is to offer the technology which can reduce the manufacturing cost of a semiconductor device.

Another purpose of the present invention is to offer the technology which can aim at improvement in the reliability of a semiconductor device.

Another purpose of the present invention is to offer the technology which can aim at miniaturization of the ignition device having a semiconductor device, reduction of a manufacturing cost, and improvement in reliability.

The above-described and the other purposes and novel features of the present invention will become apparent from the description herein and accompanying drawings.

Of the inventions disclosed in the present application, typical ones will next be summarized briefly.

The above-mentioned purpose is attained in a semiconductor device by making it the package structure using a lead frame, arranging a communication device (semiconductor chip) to the main surface side of a supporting body, and arranging the condenser for firing to the back side which is the opposite side to the main surface of the supporting body. Concretely, it is performed as follows.

(1); A semiconductor device (package) built in an ignition device for mounting over a vehicle which operates an air bag based on a signal from an electronic control unit connected to an impact sensor, comprises:

a semiconductor chip (communication device) which has a main surface and a back surface which are mutually located in an opposite side, and a controlling circuit and a plurality of electrode pads which have been arranged in the main surface;

a capacitative element (condenser for firing) which has a first and a second electrode;

a supporting body which has a main surface and a back surface which are mutually located in an opposite side;

a plurality of leads arranged around the supporting body;

a plurality of bonding wires which connect electrically the electrode pads of the semiconductor chip, and the leads; and

a resin sealing body which seals the semiconductor chip, the capacitative element, the supporting body, the leads, and the bonding wires;

wherein

the leads extend and exist continuing in and out of the resin sealing body;

the semiconductor chip is adhered over the main surface of the supporting body; and

the capacitative element is adhered over the back surface of the supporting body.

(2); A manufacturing method of a semiconductor device (package) built in an ignition device for mounting over a vehicle which operates an air bag based on a signal from an electronic control unit connected to an impact sensor, comprises the steps of:

(a) preparing a semiconductor chip (communication device) which has a main surface and a back surface which are mutually located in an opposite side, and a controlling circuit and a plurality of electrode pads which have been arranged in the main surface;

(b) preparing a capacitative element which has a first electrode and a second electrode;

(c) preparing a lead frame which has a first supporting body that has a main surface and a back surface which are mutually located in an opposite side, and a plurality of leads with which each has an inner part and an outer part, and each of the inner part has been arranged around the supporting body;

(d) adhering the semiconductor chip over the main surface of the first supporting body via a first binding material;

(e) connecting electrically the electrode pads of the semiconductor chip, and each inner part of the leads by a plurality of bonding wires;

(f) adhering the first electrode of the capacitative element over the back surface of the first supporting body via a second binding material; and

(g) forming a resin sealing body by performing resin seal of the semiconductor chip, the first supporting body, each inner part of the leads, and the bonding wires.

According to the means mentioned above, by adopting a lead frame with a reliability achievement, adhesion with the resin for sealing (mould resin) can be secured, stress reduction can be aimed at also in severe heat cycle test for automobiles of a service condition, and peeling can be suppressed.

By performing double-sided mounting of a semiconductor chip (device for communication), and the capacitative element (condenser for firing) to a lead frame, reduction of a mounting area can be aimed at, miniaturization of a semiconductor device (package) is attained and it can contribute also to the space saving (miniaturization) of the ignition device itself in contrast to an one side parallel layout.

It can respond to the terminal pitch, connection method, etc. which matched the customer's usage by changing cutting/forming shape of a lead.

Advantages achieved by some of the most typical aspects of the inventions disclosed in the present application will be briefly described below.

According to the present invention, the miniaturization of a semiconductor device can be aimed at.

According to the present invention, the manufacturing cost of a semiconductor device can be reduced.

According to the present invention, improvement in the reliability of a semiconductor device can be aimed at.

According to the present invention, the miniaturization, cost reduction, and the improvement in reliability in an ignition device which is built in a semiconductor device can be aimed at.

### BRIEF DESCRIPTION OF THE DRAWINGS

FIG. 1 is a mimetic diagram ((a) is a front view, (b) is a top view, (c) is a bottom view, and (d) is a side view) showing the appearance structure of the semiconductor device (package) which is Example 1 of the present invention;

FIG. 2 is a mimetic diagram (drawing seen from the main surface side of a supporting body) showing the internal structure of the semiconductor device which is Example 1 of the present invention;

FIG. 3 is a mimetic diagram (drawing seen from the back side of the supporting body) showing the internal structure of the semiconductor device which is Example 1 of the present invention;

FIG. 4 is a schematic sectional view taken along the a-a line of FIG. 2;

FIG. 5 is a mimetic diagram ((a) is a plan view and (b) is a sectional view taken along the b-b line of (a)) showing the structure of the lead frame used for manufacture of the semiconductor device which is Example 1 of the present invention;

FIG. 6 is a flowchart in which the manufacturing process of the semiconductor device being Example 1 of the present invention is shown;

FIG. 7 is a mimetic diagram ((a) is a plan view and (b) is a sectional view taken along the c-c line of (a)) showing a chip mounting step in manufacture of the semiconductor device which is Example 1 of the present invention;

FIG. 8 is a mimetic diagram ((a) is a plan view and (b) is a sectional view taken along the c-c line of (a)) showing a wire bonding step in manufacture of the semiconductor device which is Example 1 of the present invention;

FIG. 9 is a mimetic diagram ((a) is a plan view and (b) is a sectional view taken along the c-c line of (a)) showing a condenser mounting step in manufacture of the semiconductor device which is Example 1 of the present invention;

FIG. 10 is a schematic plan view showing a resin molding step in manufacture of the semiconductor device which is Example 1 of the present invention;

FIG. 11 is a schematic sectional view taken along the c-c line of FIG. 10;

FIG. 12 is a schematic plan view showing a marking step in manufacture of the semiconductor device which is Example 1 of the present invention;

FIG. 13 is a schematic plan view showing a lead cutting step in manufacture of the semiconductor device which is Example 1 of the present invention;

FIG. 14 is a schematic plan view showing a lead forming step in manufacture of the semiconductor device which is Example 1 of the present invention;

FIG. 15 is a mimetic diagram ((a) is a front view and (b) is a top view) showing the appearance structure of the ignition device which is Example 1 of the present invention;

FIG. 16 is a mimetic diagram ((a) is a drawing showing the internal structure taken along the X direction of FIG. 16 (a), and (b) is a drawing showing the internal structure taken along the Y direction of FIG. 16 (a)) showing the internal structure of the ignition device of FIG. 15;

FIG. 17 is the mimetic diagram which expanded a part of FIG. 16 (b);

FIG. 18 is a mimetic diagram showing the internal structure seen from the upper surface side of the ignition device of FIG. 15;

FIG. 19 is a functional block diagram of the ignition device of FIG. 15;

FIG. 20 is a functional block diagram of the control system of the airbag system which is Example 1 of the present invention;

FIG. 21 is a schematic perspective view showing one example of the gas generator with which the ignition device being Example 1 of the present invention was incorporated;

FIG. 22 is a mimetic diagram showing the steering into which the gas generator of FIG. 21 was built;

FIG. 23 is a mimetic diagram showing the condition that the air bag expanded with the gas generator of FIG. 21;

FIG. 24 is a drawing showing the operation procedures at the time of protective-gear diagnosis of the airbag system which is Example 1 of the present invention;

FIG. 25 is a mimetic diagram of the vehicle at the time of safety;

FIG. 26 is a drawing showing the operation procedures at the time of the collision of the airbag system which is Example 1 of the present invention;

FIG. 27 is a mimetic diagram of the vehicle at the time of a collision; and

FIG. 28 is a schematic sectional view showing the internal structure of the ignition device which is the example 2 of the present invention.

### EXPLANATION OF REFERENCE NUMERALS

1 semiconductor device (package)
2 semiconductor chip
3 (p1-p6) electrode pad
4 chip type condenser
4a, 4b electrode
5 (A1, A2, B1, B2) lead
5a inner part
5b outer part
6 supporting body (chip mounting part)
6a wire connecting part
7 supporting body
8 suspension lead
9 binding material
10 bonding wire
11 binding material
12 resin sealing body
15 frame body
16 product formation area
17 resin molding region (molding region)
19 distinguishing mark
LF lead frame
20 controlling circuit
21 controller
22 ASRB driver
23 power supply circuit
24 firing circuit
25 diagnosing circuit
26 clock circuit
30 ignition device
31 case (casing)
32 header
33a, 33b lead pin
34 firing element
35 electrode pad
36 resistor (firing part)
37 bonding wire
38 gunpowder
40 electronic control unit
41 impact detection sensor
42a, 42b bus
50 gas generator
51 firing agent
52 gas generation agent
53 filter

### BEST MODE FOR CARRYING OUT THE INVENTION

In the below-described embodiments (examples), a description will be made after divided in plural sections or in plural embodiments if necessary for convenience's sake. These plural sections or embodiments are not independent each other, but in a relation such that one is a modification example, details or complementary description of a part or whole of the other one unless otherwise specifically indicated. And, in the below-described embodiments, when a reference is made to the number of elements (including the number, value, amount and range), the number is not limited to a specific number but can be greater than or less than the specific number unless otherwise specifically indicated or principally apparent that the number is limited to the specific number. Furthermore, in the below-described embodiments, it is needless to say that the constituting elements (including element steps) are not always essential unless otherwise specifically indicated or principally apparent that they are essential. Similarly, in the below-described embodiments, when a reference is made to the shape or positional relationship of the constituting elements, that substantially analogous or similar to it is also embraced unless otherwise specifically indicated or principally apparent that it is not. This also applies to the above-described value and range. And, in all the drawings for describing the embodiments, members of a like function will be identified by like reference numerals and overlapping descriptions will be omitted. Hereafter, embodiments of the invention are explained in detail based on drawings.

### EXAMPLE 1

The Example 1 explains the example which applied the present invention to the ignition device used for the airbag system for mounting on a vehicle of a bus-connection method, and the semiconductor device (a package, electronic parts) built in this ignition device (squib).

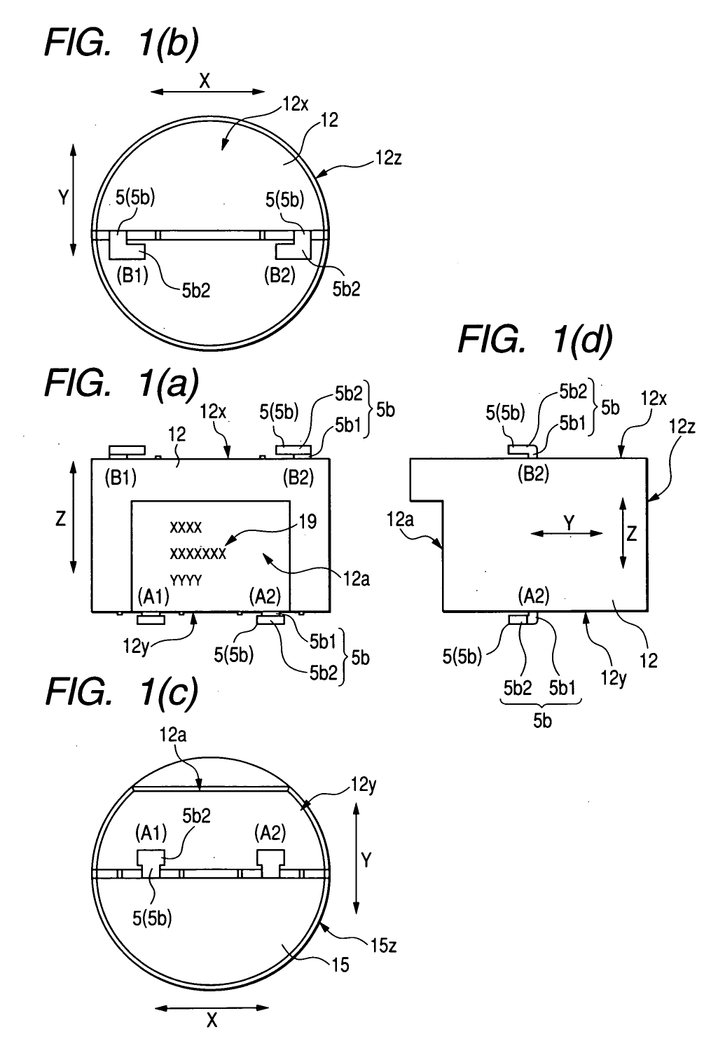

FIG. 1 through FIG. 23 are the drawings concerning Example 1 of the present invention,

FIG. 1 is a mimetic diagram ((a) is a front view, (b) is a top view, (c) is a bottom view, and (d) is a side view) showing the appearance structure of the semiconductor device (package) built in an ignition device,

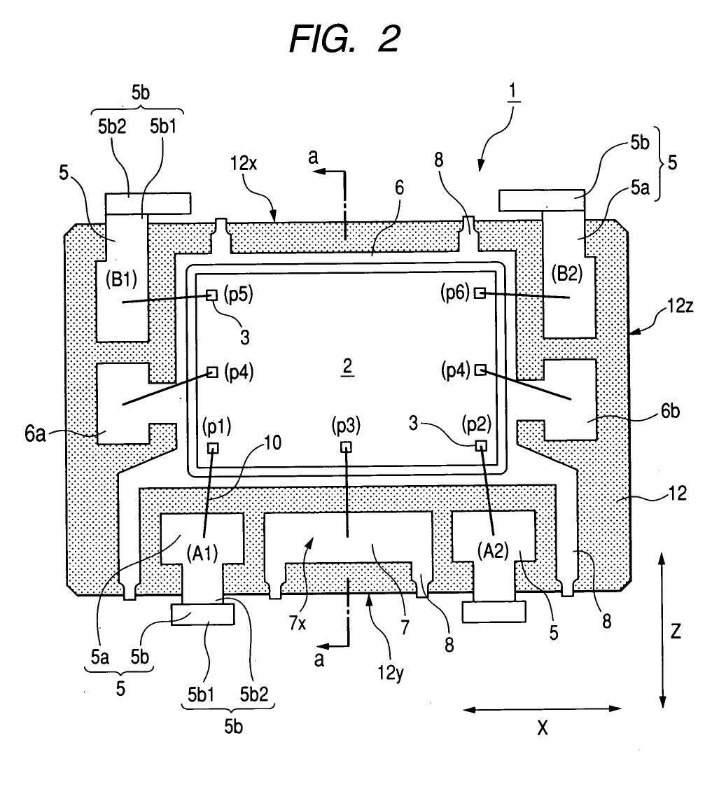

FIG. 2 is a mimetic diagram (drawing seen from the main surface side of a supporting body) showing the internal structure of said semiconductor device,

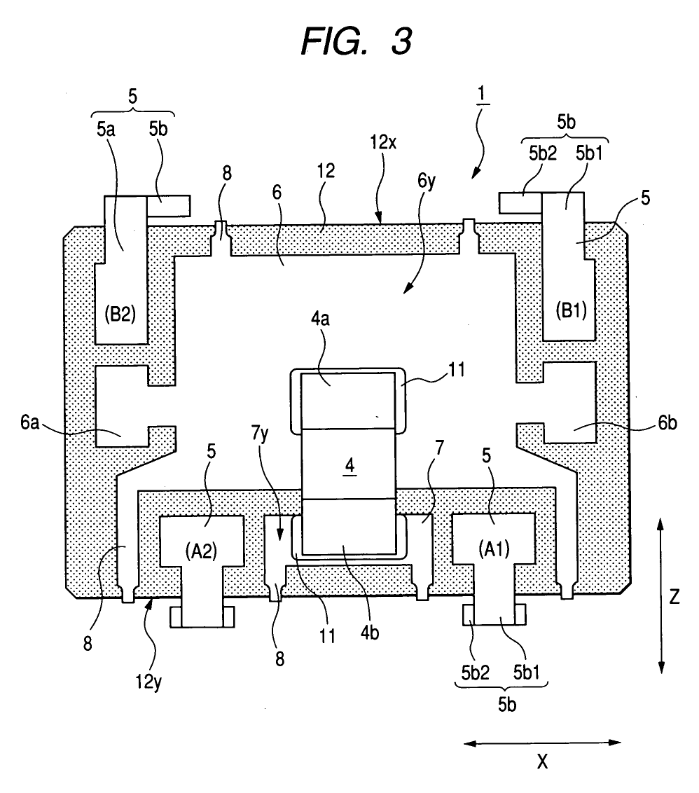

FIG. 3 is a mimetic diagram (drawing seen from the back side of the supporting body) showing the internal structure of said semiconductor device,

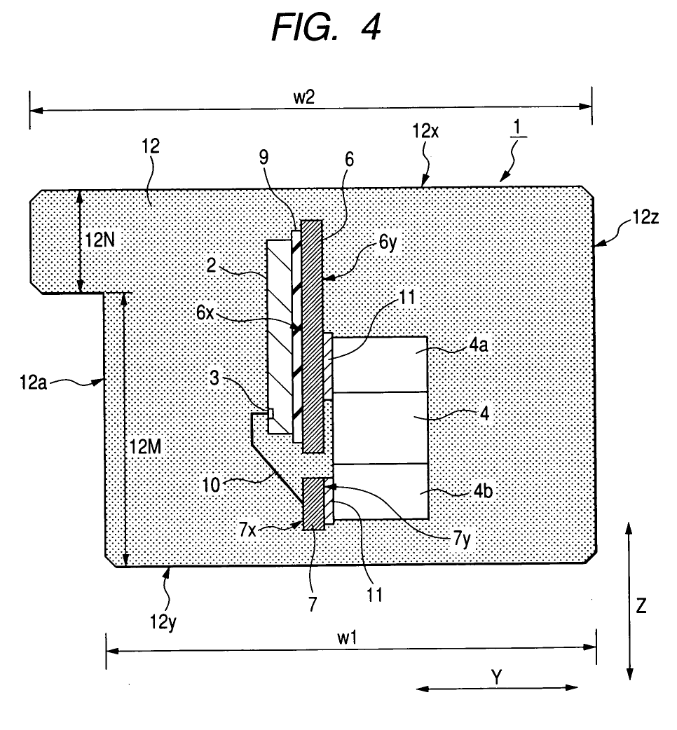

FIG. 4 is a schematic sectional view taken along the a-a line of FIG. 2,

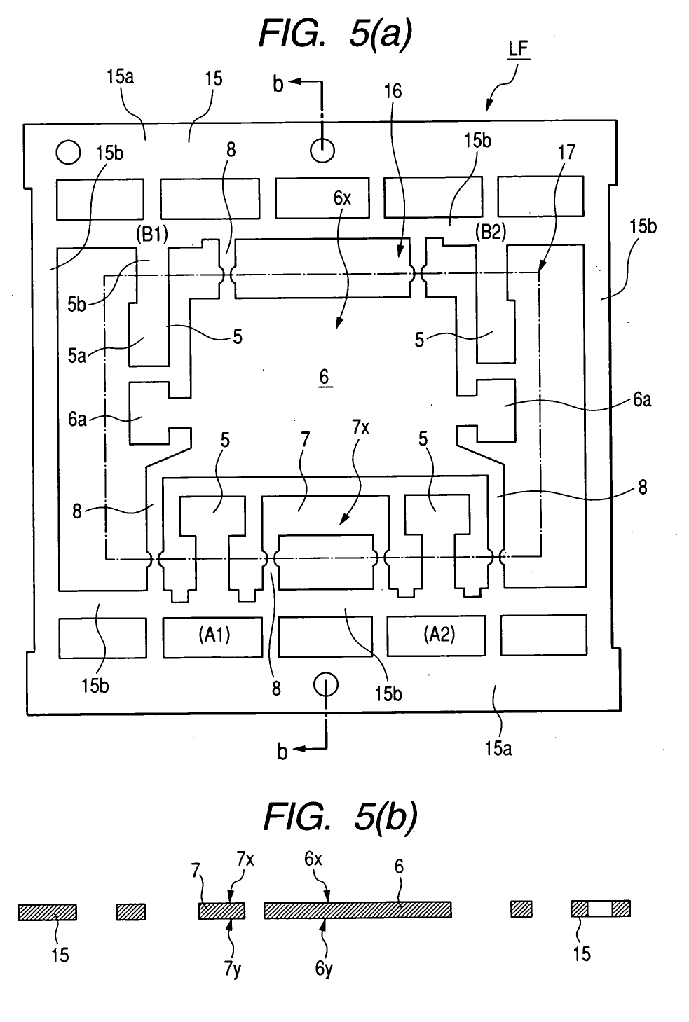

FIG. 5 is a mimetic diagram ((a) is a plan view and (b) is a sectional view taken along the b-b line of (a)) showing the structure of the lead frame used for manufacture of said semiconductor device,

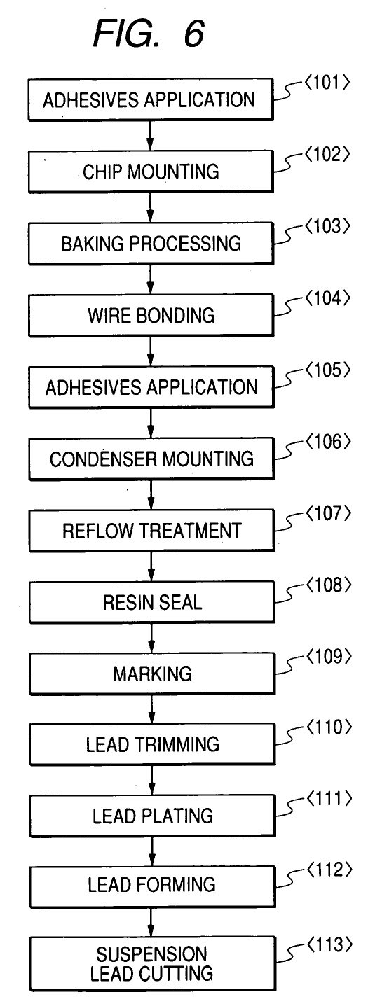

FIG. 6 is a flowchart in which the manufacturing process of said semiconductor device is shown,

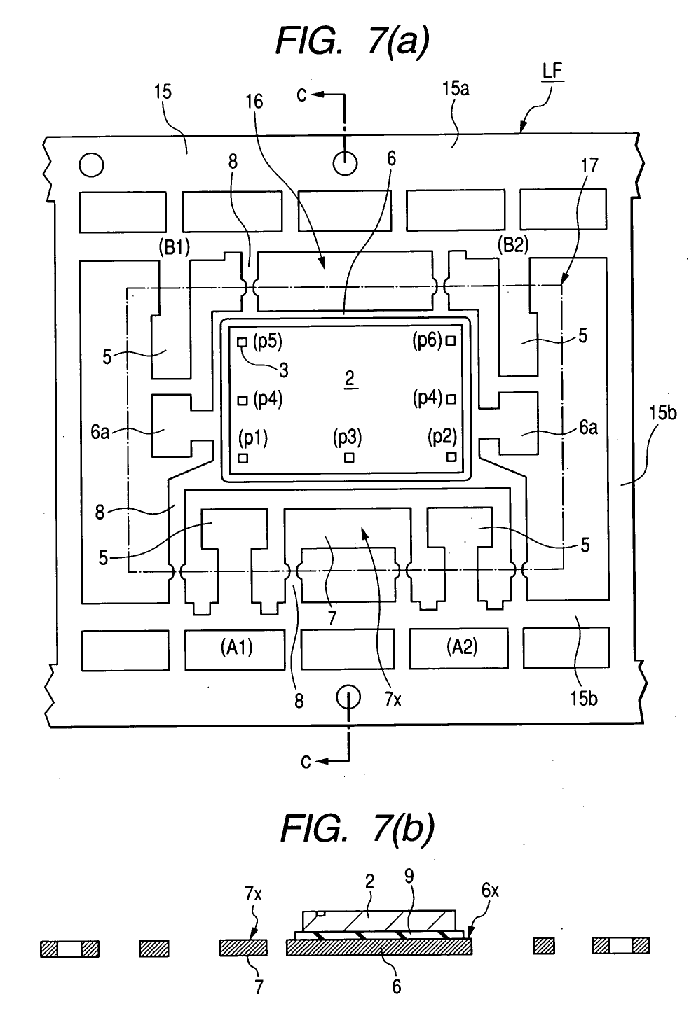

FIG. 7 is a mimetic diagram ((a) is a plan view and (b) is a sectional view taken along the c-c line of (a)) showing a chip mounting step in manufacture of said semiconductor device,

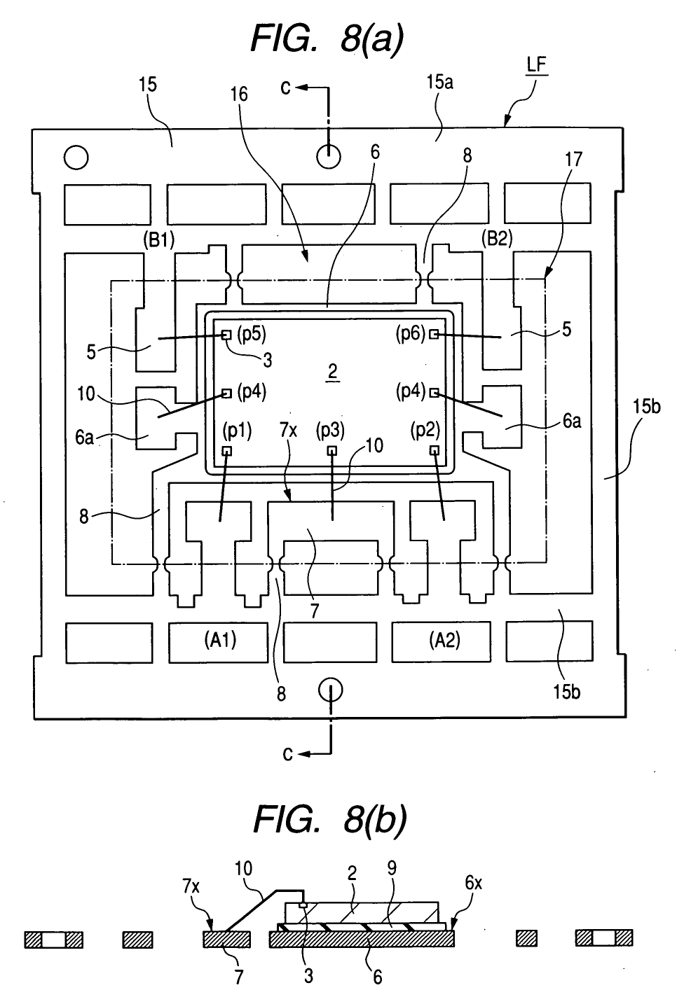

FIG. 8 is a mimetic diagram ((a) is a plan view and (b) is a sectional view taken along the c-c line of (a)) showing a wire bonding step in manufacture of said semiconductor device,

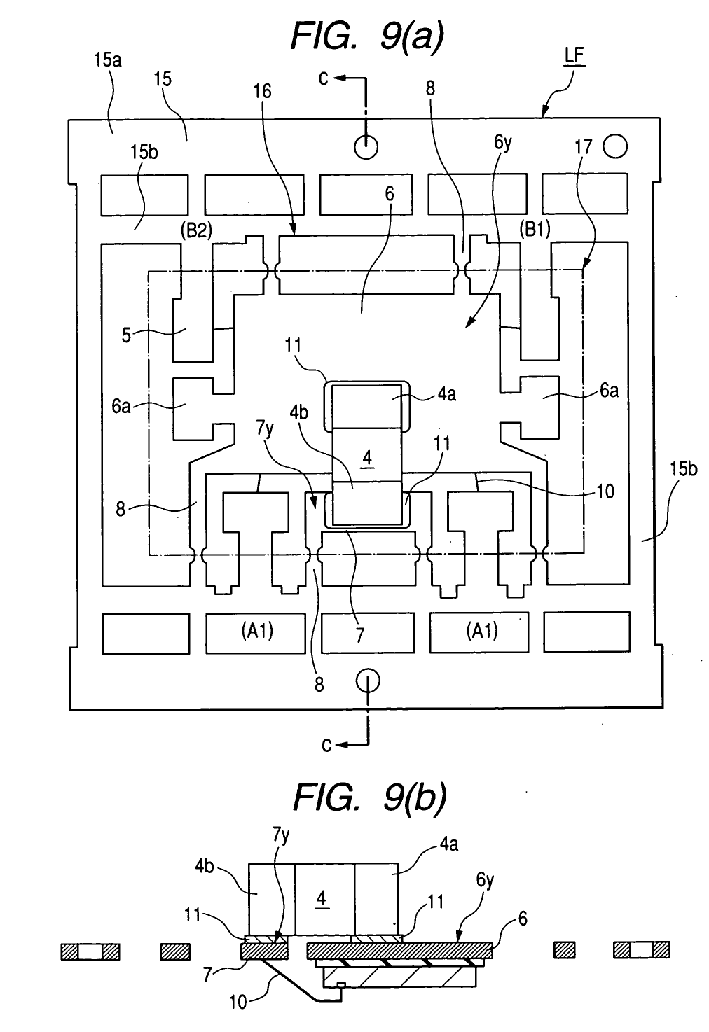

FIG. 9 is a mimetic diagram ((a) is a plan view and (b) is a sectional view taken along the c-c line of (a)) showing a condenser mounting step in manufacture of said semiconductor device,

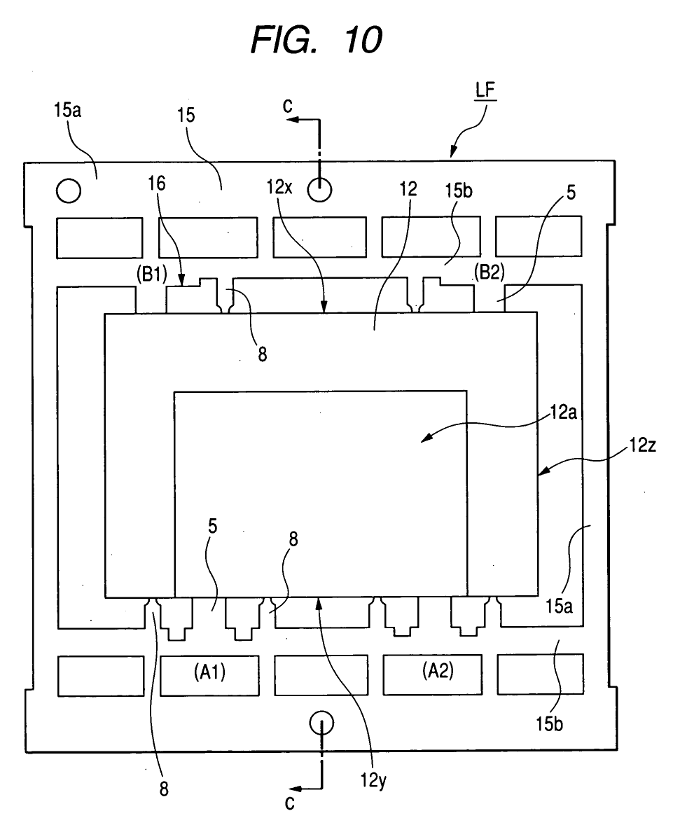

FIG. 10 is a schematic plan view showing a resin molding step in manufacture of said semiconductor device,

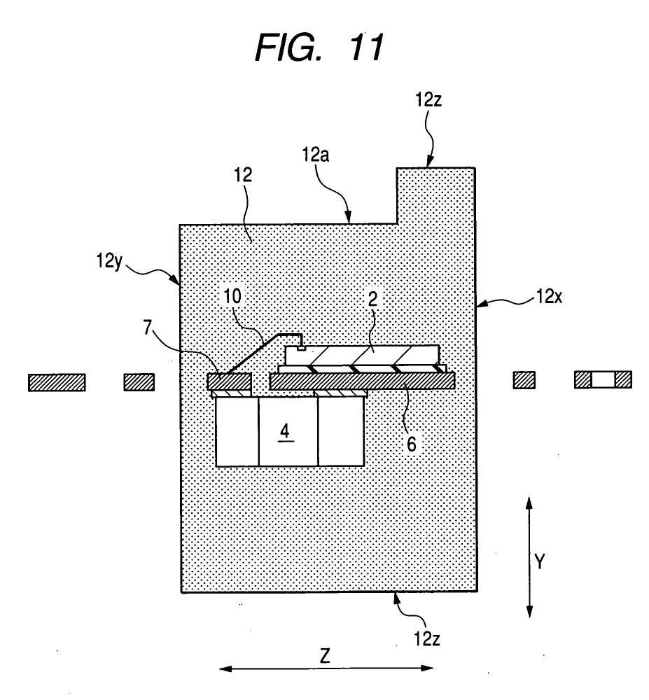

FIG. 11 is a schematic sectional view taken along the c-c line of FIG. 10,

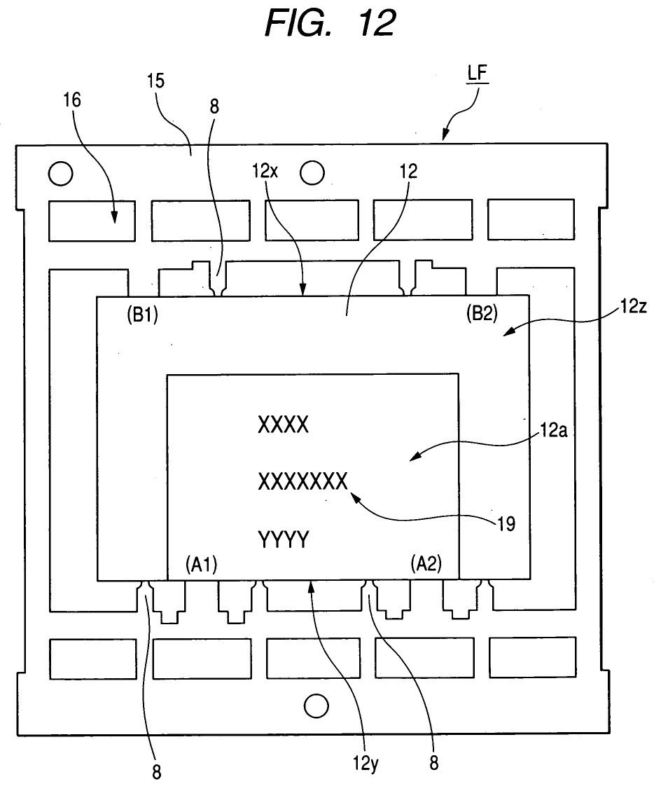

FIG. 12 is a schematic plan view showing a marking step in manufacture of said semiconductor device,

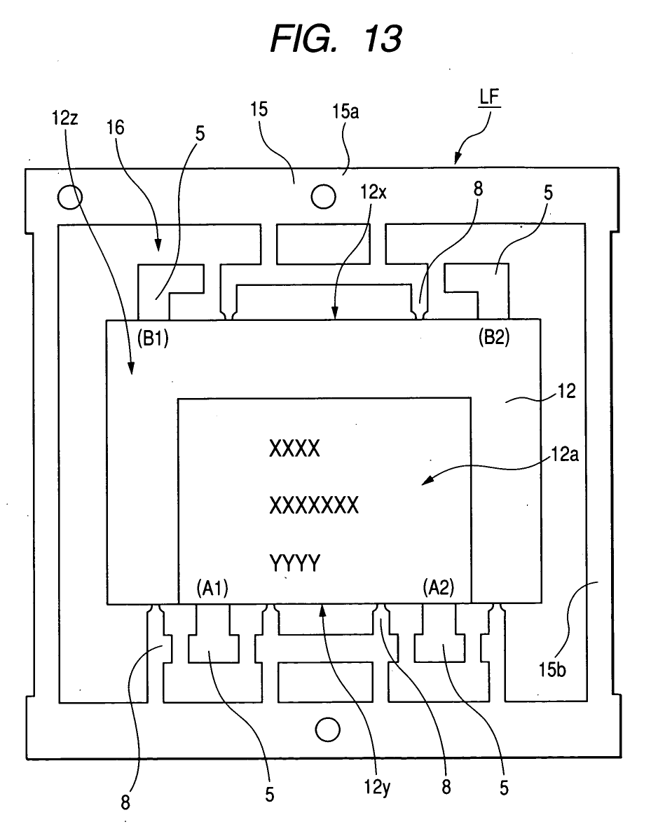

FIG. 13 is a schematic plan view showing a lead cutting step in manufacture of said semiconductor device,

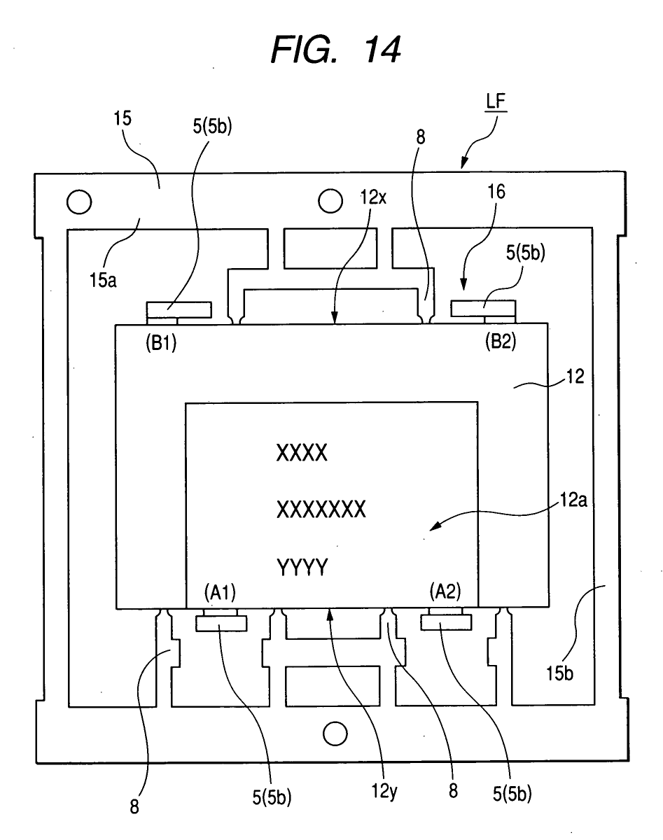

FIG. 14 is a schematic plan view showing a lead forming step in manufacture of said semiconductor device,

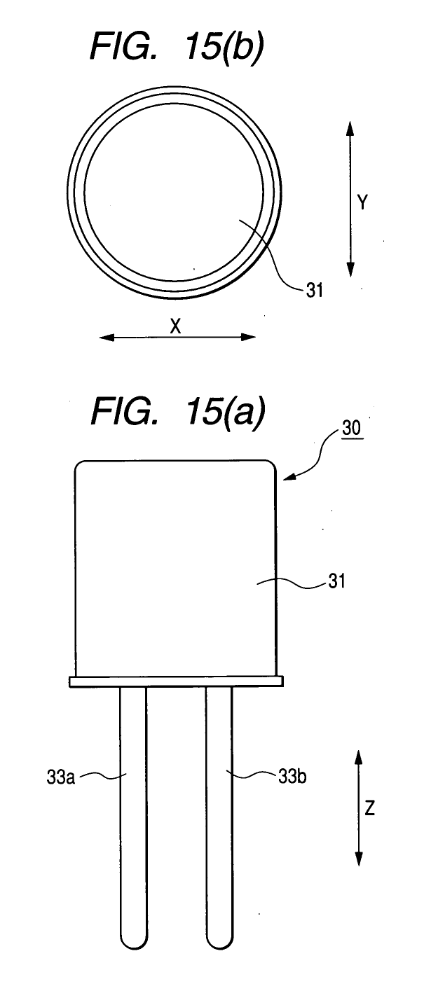

FIG. 15 is a mimetic diagram ((a) is a front view and (b) is a top view) showing the appearance structure of the ignition device having said semiconductor device,

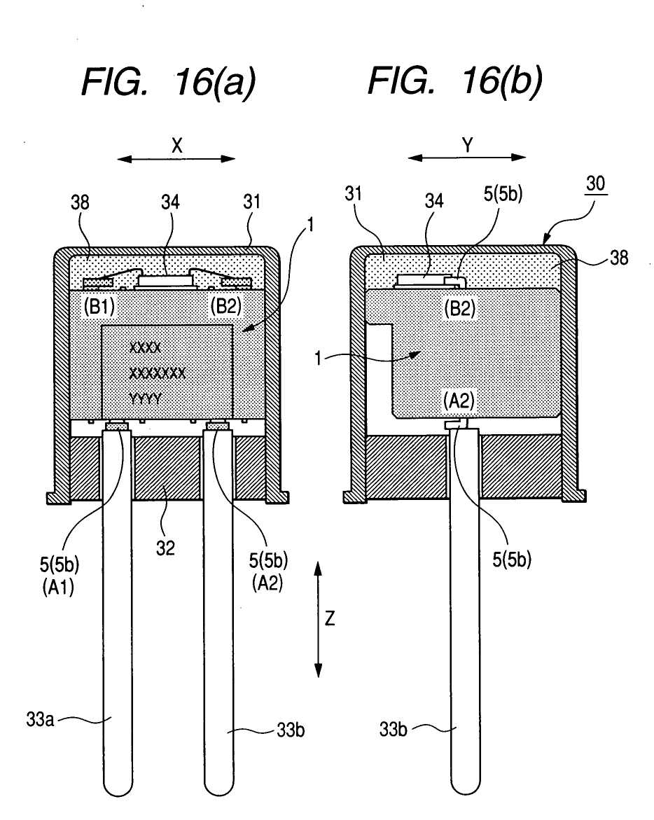

FIG. 16 is a mimetic diagram ((a) is a drawing showing the internal structure taken along the X direction of FIG. 16 (a), and (b) is a drawing showing the internal structure taken along the Y direction of FIG. 16 (a)) showing the internal structure of said ignition device,

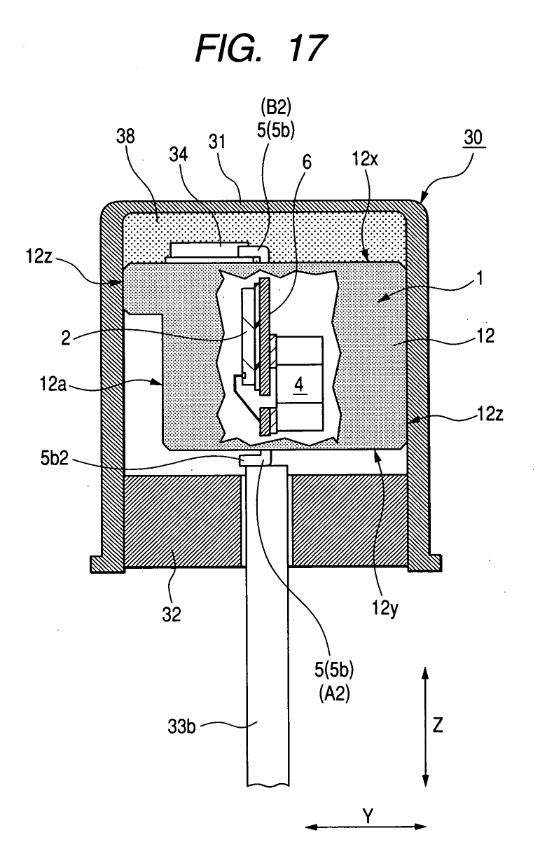

FIG. 17 is the mimetic diagram which expanded a part of FIG. 16 (b),

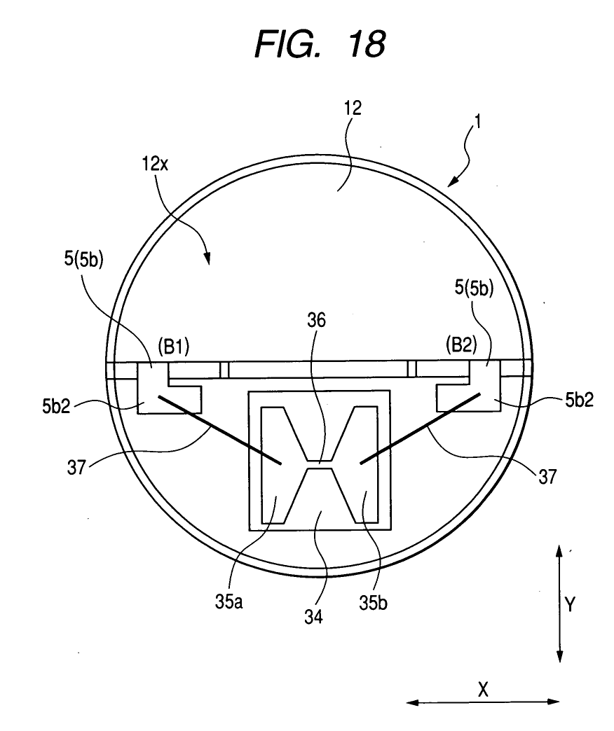

FIG. 18 is a mimetic diagram showing the internal structure seen from the upper surface side of said ignition device,

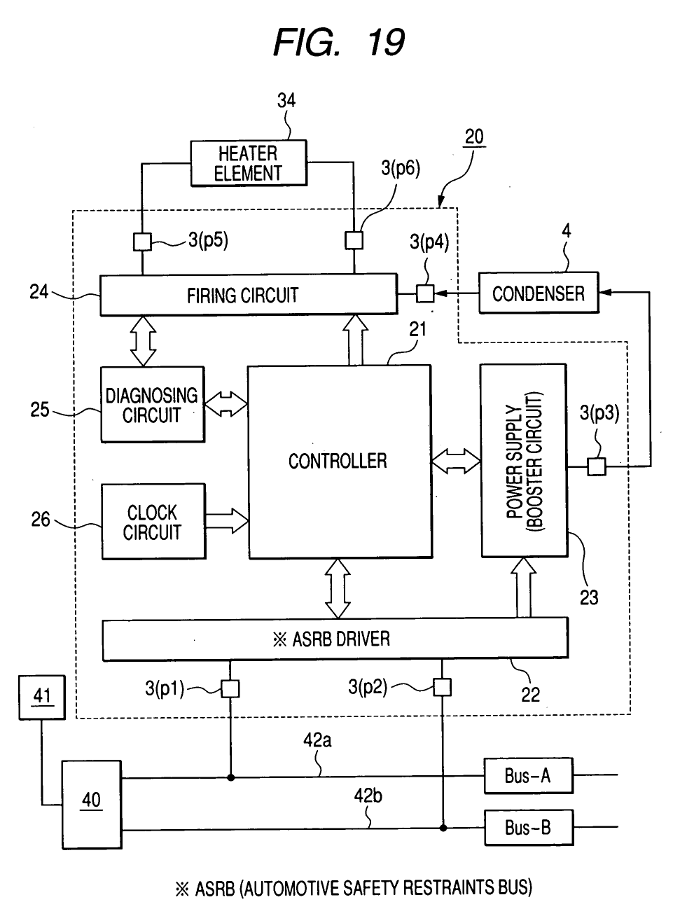

FIG. 19 is a functional block diagram of said ignition device,

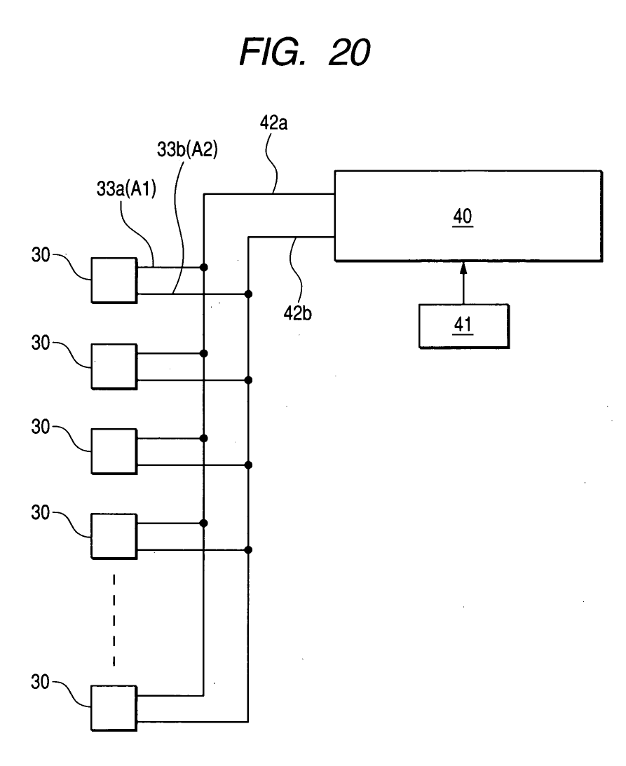

FIG. 20 is a functional block diagram of the control system of the airbag system which uses said ignition device,

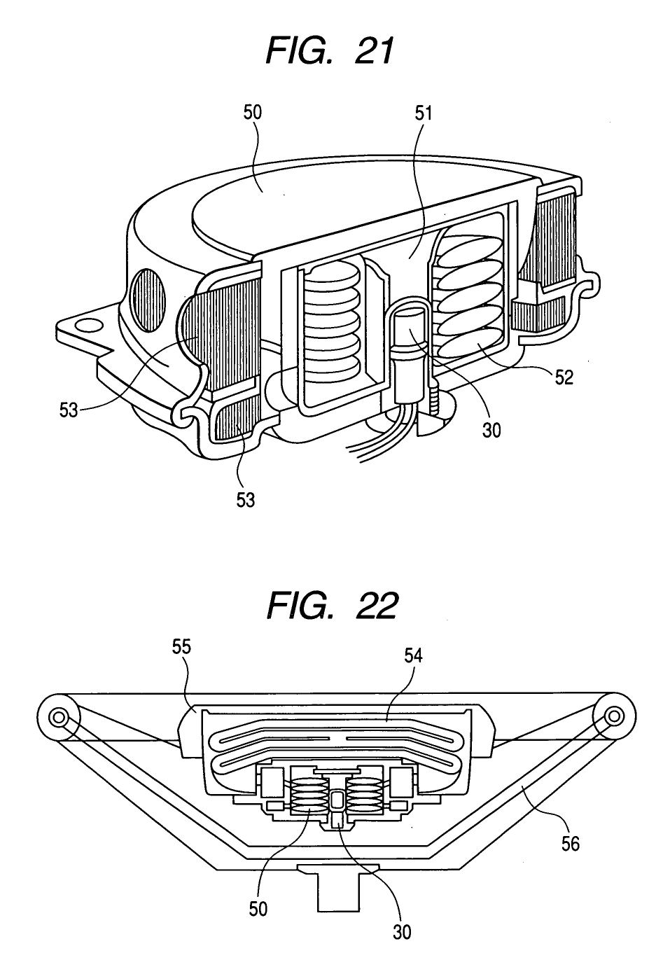

FIG. 21 is a schematic perspective view showing one example of the gas generator incorporating said ignition device,

FIG. 22 is a mimetic diagram showing the steering incorporating said gas generator,

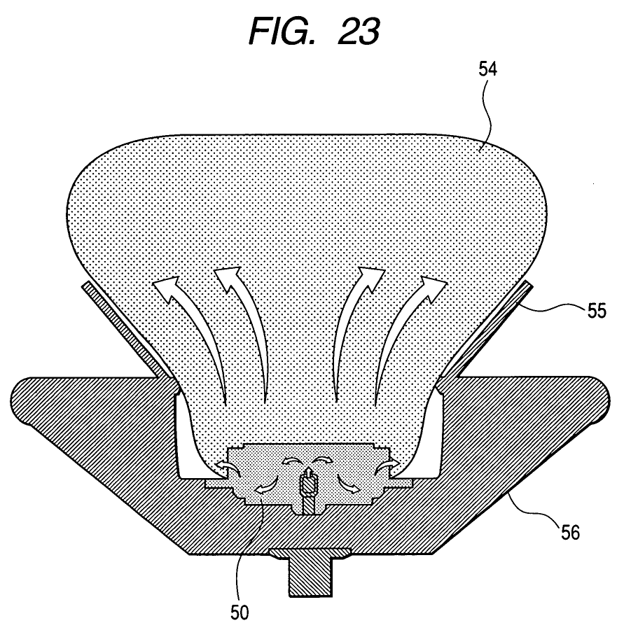

FIG. 23 is a mimetic diagram showing the condition that the air bag expanded with said gas generator,

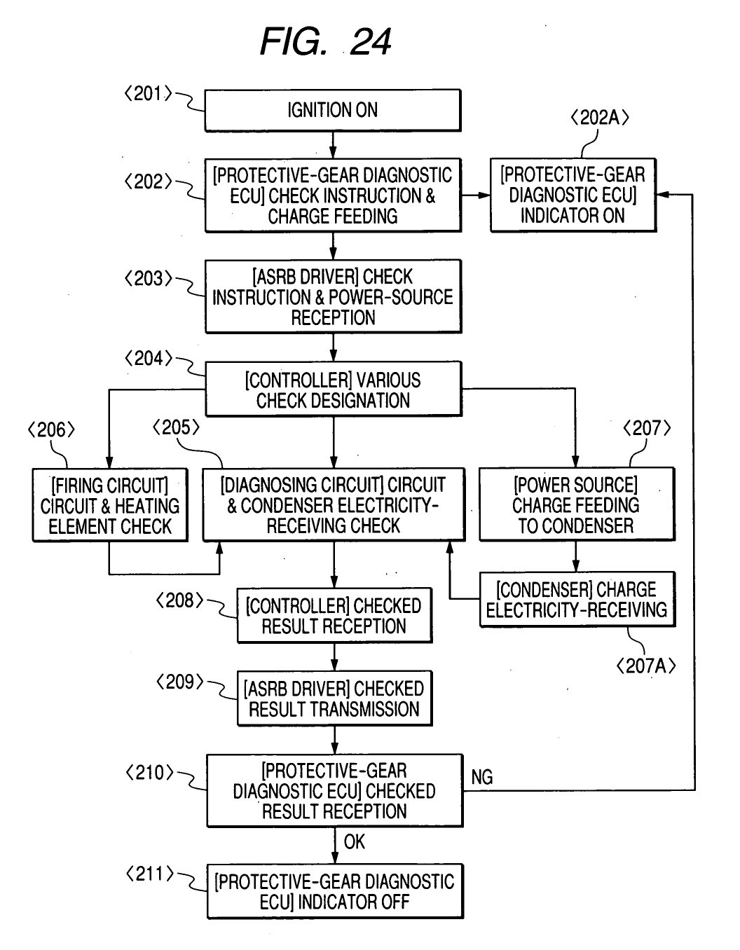

FIG. 24 is a drawing showing the operation procedures at the time of protective-gear diagnosis of said airbag system,

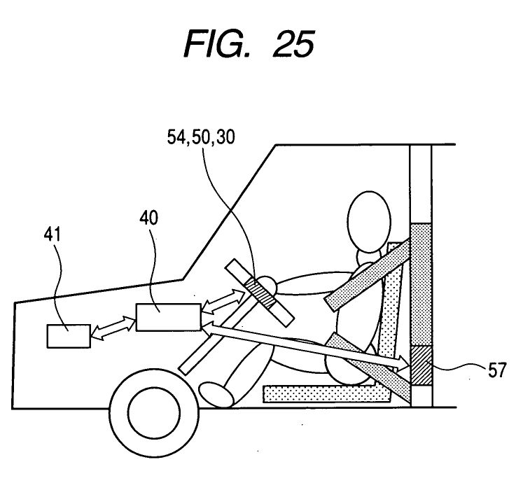

FIG. 25 is a mimetic diagram of the vehicle at the time of safety,

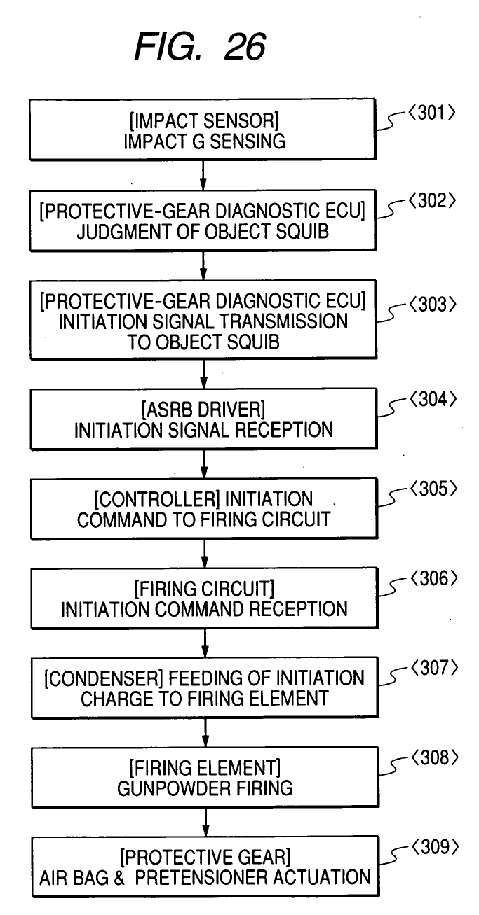

FIG. 26 is a drawing showing the operation procedures at the time of the collision of said airbag system, and

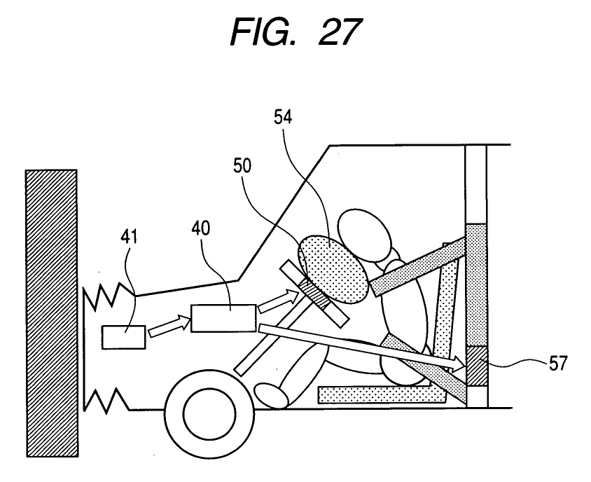

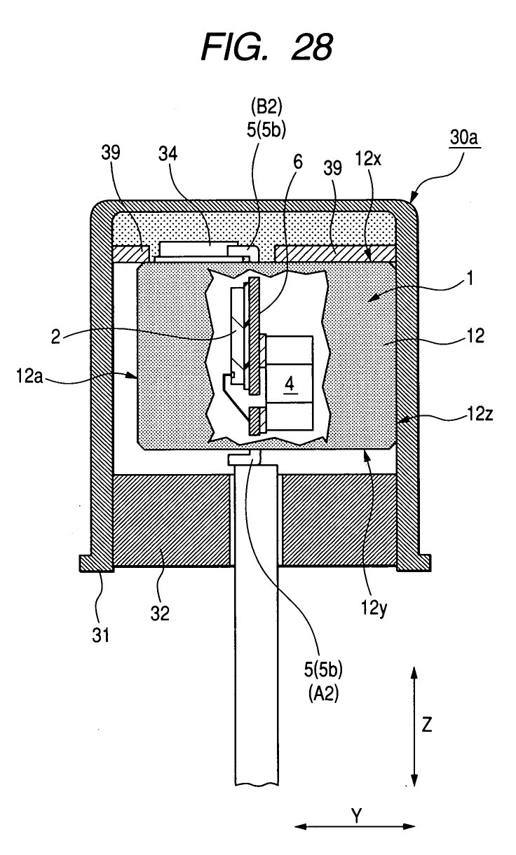

FIG. 27 is a mimetic diagram of the vehicle at the time of a collision.

As shown in FIG. 20, in the airbag system, impact detection sensor 41 which detects the collision of a car is connected to electronic control unit (protective-gear diagnostic ECU) 40 which controls the action of an air bag device. A plurality of ignition devices 30 are connected to two buses (external bus: 42a, 42b) which extend from electronic control unit 40. Ignition device 30 is built into the gas generator of an air bag device, and there are an air bag device developed from a steering, an air bag device developed from a dashboard, an air bag device developed from the side part of a seat or the side part of a roof, etc. as an air bag device.

Here, although it is one example of an air bag device, the air bag device developed from a steering mainly has gas generator (inflator) 50 shown in FIG. 21, ignition device 30 built into this gas generator 50, air bag 54, module covering 55 which are shown in FIG. 22, etc., and as shown in FIG. 22, it is included in steering body 56. Gas generator 50 has firing agent 51, gas generation agent 52, filter 53, etc., as shown in FIG. 21. Firing agent 51 burns with firing to ignition device 30, and gas generation agent 52 burns by burning of this firing agent 51. With filter 53, the high pressure gas which occurred by burning of this gas generation agent 52 is cooled and purified, and is emitted, and with the high pressure gas cooled and purified with filter 53, as shown in FIG. 23, air bag 54 expands.

Next, semiconductor device 1 built in ignition device 30 is explained.

As shown in FIG. 2 through FIG. 4, semiconductor device (package) 1 has the package structure which molded semiconductor chip 2, condenser (capacitative element) 4, a plurality of leads (four (A1, A2, B1, B2) in Example 1) 5, a supporting body (6, 7), wire connecting part (two in Example 1) 6a, a plurality of suspension leads 8, a plurality of bonding wires 10, etc. with the resin of resin sealing body 12.

As for semiconductor chip 2, the plane shape which intersects a thickness direction is rectangular shape, and has a rectangle in Example 1. Although semiconductor chip 2 is not limited to this, it has the structure of having a semiconductor substrate, the transistor element formed in the main surface of this semiconductor substrate, and the thin film layered product (multilayer interconnection object) which accumulated two or more stages of each of the insulating layer and the wiring layer on the main surface of a semiconductor substrate, for example. The single crystal silicon substrate, for example is used as a semiconductor substrate. As an insulating layer of a thin film layered product, a silicon oxide film is used, for example and metal films, such as aluminum (Al), an aluminum alloy, copper (Cu), or a Cu alloy, are used as a wiring layer, for example.

Semiconductor chip 2 has the main surface and back surface which are mutually located in the opposite side, and controlling circuit 20 shown in FIG. 19 is mounted in the main surface side of semiconductor chip 2 as an integrated circuit. A plurality of electrode pads (bonding pad: p1-p6) 3 are arranged on the main surface of semiconductor chip 2. In Example 1, a plurality of electrode pads 3 are arranged along three sides (two short sides and one long side) of the main surface of semiconductor chip 2. Each of a plurality of electrode pads 3 is formed in the wiring layer of the top layer in the thin film layered product of semiconductor chip 2, and is exposed by bonding opening formed in the insulating layer (protective film) of the top layer in the thin film layered product of semiconductor chip 2 corresponding to each.

As for supporting body (the first supporting body, a lead frame, a chip mounting part) 6, the plane shape which intersects a thickness direction is rectangular shape, and has a rectangle in Example 1. Supporting body 6 is platy. Supporting body 6 has main surface (first surface) 6x and back surface (second surface) 6y which are mutually located in the opposite side, and is formed in larger plane size than semiconductor chip 2.

The back surface of semiconductor chip 2 has been adhered to main surface 6x of supporting body 6 via binding material 9.

Each of a plurality of leads (lead terminal: A1, A2, B1, B2) 5 is arranged around supporting body 6. Each of a plurality of leads 5 has the structure of having inner part 5a and outer part 5b connected with this inner part 5a in one. Inner part 5a is a portion sealed by resin sealing body 12, and is located in the inside of resin sealing body 12. Outer part 5b is a portion drawn to the outside of resin sealing body 12, and is located in the outside of resin sealing body 12. That is, each of a plurality of leads 5 is extended and existed continuing within and without resin sealing body 12.

Each of a plurality of leads 5 has the main surface and back surface which are mutually located in the opposite side. Each main surface of a plurality of leads 5 is located in the main surface 6x side (the same side as main surface 6x of supporting body 6) of supporting body 6 in the thickness direction of supporting body 6.

Supporting body (second supporting body) 7 is arranged around supporting body 6. Supporting body 7 has main surface (first surface) 7x and back surface (second surface) 7y which are mutually located in the opposite side. Main surface 7x of supporting body 7 is located in the main surface 6x side (the same side as main surface 6x of supporting body 6) of supporting body 6 in the thickness direction of supporting body 6.

Two wire connecting parts 6a are arranged around supporting body 6, and are connected with supporting body 6 in one. Each of two wire connecting parts 6a has the main surface and back surface which are mutually located in the opposite side. Each main surface of two wire connecting parts 6a is located in the main surface side (the same side as main surface 6x of supporting body 6) of supporting body 6 in the thickness direction of supporting body 6.

Each of a plurality of electrode pads (p1-p6) 3 of semiconductor chip 2 is electrically connected with a plurality of leads 5 arranged around supporting body 6, supporting body 7, and two wire connecting parts 6a by a plurality of bonding wires 10, respectively. Concretely, electrode pad p1 is connected with lead A1 electrically via bonding wire 10, electrode pad p2 is electrically connected with lead A2 via bonding wire 10, electrode pad p3 is electrically connected with supporting body 7 via bonding wire 10, electrode pad p4 is electrically connected with connecting part 6a via bonding wire 10, electrode pad p5 is electrically connected with lead B1 via bonding wire 10, and electrode pad p6 is electrically connected with lead B2 via bonding wire 10.

As for bonding wire 10 which connects electrically electrode pad p1, p2, p5, and p6, and lead A1, A2, B1 and B2, respectively, the one end side is connected to electrode pad 3 (p1, p2, p5, p6), and the other end side is connected to the main surface of inner part 5b of lead (A1, A2, B1, B2) 5. The one end side is connected to electrode pad p3, and, as for bonding wire 10 which connects electrically electrode pad p3 and supporting body 7, the other end side is connected to main surface 7x of supporting body 7. The one end side is connected to electrode pad p4, and, as for bonding wire 10 which connects electrically electrode pad p4 and wire connecting part 6a, the other end side is connected to the main surface of wire connecting part 6a.

As bonding wire 10, Au wire is used, for example. As a connection method of bonding wire 10, the nailhead-bonding (ball bonding) method which used supersonic vibration together, for example to thermo compression bonding is used.

In a plurality of leads 5, supporting bodies 6 and 7, and wire connecting parts 6a, in order to aim at improvement in bondability with bonding wire 10, Ag plating is performed to the portion to which bonding wire 10 is connected.

Condenser 4 is formed with the surface mounting type (chip type) of the rectangle object which has an electrode (4a, 4b) to the ends which oppose mutually. About condenser 4, one electrode 4a is adhered to back surface 6y of supporting body 6 via electrically conductive binding material 11, and electrode 4b of another side is adhered to back surface 7y of supporting body 7 via electrically conductive binding material 11, and both are connected electrically and mechanically. As condenser 4, the capacity is for example, 2.2□F and the larger thing than the capacity applied to a server etc. is used. One electrode 4a of condenser 4 outputs power supply potential to semiconductor chip 2 from condenser 4, and, as for electrode 4b of another side, a control signal and power supply potential are supplied from semiconductor chip 2. That is, since two electrodes (4a, 4b) differ in an electric operation processing, supporting body 6 and 7 are separated electrically. Thereby, semiconductor device 1 has a portion where semiconductor chip 2 and condenser 4 are not lapping superficially (the Y direction shown in FIG. 4).

Resin sealing body 12 is formed in the cylinder shape whose upper surface 12x and under surface 12y which are mutually located in the opposite side become from a plane, and whose side surface 12z becomes from a curved surface, as shown in FIG. 1 ((a), (b), (c), (d)). Resin sealing body 12 includes thermosetting resin of an epoxy system with which a phenol system curing agent, silicone rubber, a filler, etc. were added as a purpose which aims at stress reduction, for example, and is formed by the suitable transfer molding method for a mass production method. The transfer molding method is the method of using the forming mold provided with the pot, the runner, the resin injection gate, the mold cavity, etc., pouring in resin into a mold cavity through a runner and a resin injection gate from a pot, and forming a resin sealing body.

Resin sealing body 12 has plane 12a on a part of side surface 12z, and marking of the distinguishing mark 19 which displays information, including a name of article, a company name, a kind, a manufacture lot number, etc., is performed to this plane 12a. In Example 1, plane 12a is spaced out and formed from upper surface 12x of resin sealing body 12, and continues to under surface 12y of resin sealing body 12. That is, resin sealing body 12 comprises lower part 12M whose side surface 12z becomes from a curved surface and plane 12a, and 12N of the upper part whose side surface 12z becomes from a curved surface in the height direction (a thickness direction, a Z direction), as shown in FIG. 4. In the direction which intersects perpendicularly in contrast to plane 12a (direction which intersects perpendicularly in contrast to main surface 6x of supporting body 6 (the Y direction)), width w1 of lower part 12M is smaller than width (diameter) w2 of 12N of upper part. In Example 1, width w2 of the Y direction of 12N of upper part is about 6 mm, and width w1 of the Y direction of lower part 12M is about 4.55 mm. The height (thickness) of the Z direction of resin sealing body 12 is about 4 mm, about the dimension of plane 12a, the height of a Z direction is about 3 mm, and the width of the X direction is about 3.5 mm.

Plane 12a of resin sealing body 12 is, as shown in FIG. 4, formed along main surface 6x of supporting body 6 (parallel to the plane of main surface 6x of supporting body 6), and is formed at the opposite side to condenser 4 bordering supporting body 6 (semiconductor chip 2 side).

As shown in FIG. 2 through FIG. 4, semiconductor chip 2, supporting bodies 6 and 7, and a plurality of leads 5 are arranged as each main surface is situated along the height direction (Z direction) of resin sealing body 12. That is, semiconductor device 1 has the vertical type structure which stood semiconductor chip 2 and condenser 4 in contrast to under surface 12y and upper surface 12x of resin sealing body 12 in the inside of resin sealing body 12.

As shown in FIG. 2 and FIG. 3, lead (A1, A2) 5 has been arranged at the outside of one long side of supporting body 6, and is projected from under surface 12y of resin sealing body 12. Supporting body 7 is arranged between lead (A1) 5 and lead (A2) 5 at the outside of one long side of supporting body 6. Lead (B1) 5 has been arranged at the outside of one short side of supporting body 6, and is projected from upper surface 12x of resin sealing body 12. Lead (B2) 5 has been arranged at the outside of the short side of another side of supporting body 6, and is projected from upper surface 12x of resin sealing body 12. One wire connecting part 6a is arranged at the outside of one short side of supporting body 6, and wire connecting part 6a of another side is arranged at the outside of the short side of another side of supporting body 6.

In supporting body 6, four suspension leads 8 are connected in a row in one. Among four, as for two suspension leads 8, the one end side is connected with supporting body 6 in the side of one long side of supporting body 6, and the other end side is prolonged toward under surface 12y of resin sealing body 12. As for the two remaining suspension leads 8, the one end side is connected with supporting body 6 in the side of the long side of another side of supporting body 6, and the other end side is prolonged toward upper surface 12x of resin sealing body 12.

In supporting body 7, two suspension leads 8 are connected in a row in one, and these two suspension leads 8 are prolonged toward under surface 12y of resin sealing body 12.

As shown in FIG. 1 ((a), (b), (c), (d)), FIG. 2, and FIG. 3, each outer part 5b of two leads (A1, A2) 5 has the structure of having first portion 5b1 that projects from under surface 12y of resin sealing body 12, and second portion 5b2 that bends from this first portion 5b1 in the direction along under surface 12y of resin sealing body 12. This second portion 5b2 is used as a terminal for external connection, and a lead pin is connected in the assembling process of an ignition device.

Each outer part 5b of two leads (B1, B2) 5 has the structure of having first portion 5b1 that projects from upper surface 12x of resin sealing body 12, and second portion 5b2 that bends from this first portion 5b1 in the direction along upper surface 12x of resin sealing body 12. This second portion 5b2 is used as a terminal for external connection, and a bonding wire is connected in the assembling process of an ignition device.

In each outer part 5b of two leads (B1, B-2) 5, in order to aim at improvement in a bondability with a bonding wire, Ni plating is performed to the portion to which a bonding wire is connected.

In outer part 5b of a plurality of leads (A1, A2, B1, B2) 5, second portion 5b2 has the structure of having a portion whose width is wider than first portion 5b1.

As shown in FIG. 19, controlling circuit 20 has controller 21, ASRB (Automotive Safety Restraints Bus) driver 22, power supply circuit (booster circuit) 23, firing circuit 24, diagnosing circuit 25, clock circuit 26, etc., and these are mutually connected via the bus (an internal bus, I/O BUS).

Electrode pad (p1, p2) 3 is electrically connected with ASRB driver 22, electrode pad (p3) 3 is electrically connected with power supply circuit 23, and electrode pad (p4, p5, p6) 3 is electrically connected with firing circuit 24.

Namely, lead (A1) 5 is electrically connected with ASRB driver 22 via bonding wire 10 and electrode pad (p1) 3 as shown in FIG. 2 and FIG. 19, and lead (A2) 5 is electrically connected with ASRB driver 22 via bonding wire 10 and electrode pad (p2) 3. Lead (first lead terminal: A1 or A2) 5 is a lead (terminal) with which power supply potential is supplied (outputted), and the control signal which controls controlling circuit 20 of semiconductor chip 2 is supplied (outputted). Lead (B1) 5 is electrically connected with firing circuit 24 via bonding wire 10 and electrode pad (p5) 3, and lead (B2) 5 is electrically connected with firing circuit 24 via bonding wire 10 and electrode pad (p6) 3. Lead (third lead terminal: B1 and B2) 5 is a terminal which outputs the control signal supplied from controlling circuit 20 of semiconductor chip 2 (output) to firing element 34 based on said control signal. As shown in FIG. 2, FIG. 3, and FIG. 19, one electrode 4a of condenser 4 is electrically connected with firing circuit 24 via supporting body 6, wire connecting part 6a, bonding wire 10, and electrode pad (p4) 3. Wire connecting part (fourth lead terminal) 6a is a terminal with which the power supply potential supplied (outputted) to controlling circuit 20 of semiconductor chip 2 is supplied (outputted) from condenser 4. Electrode 4b of another side of condenser 4 is electrically connected with power supply circuit 23 via supporting body 7, bonding wire 10, and electrode pad (p3) 3. Supporting body 7 (second lead terminal) is a terminal which outputs the power supply potential and the control signal which are supplied (outputted) from controlling circuit 20 of semiconductor chip 2.

A plurality of leads 5, supporting bodies 7, and wire connecting parts 6a may be regarded as lead terminals.

Semiconductor device 1 constituted in this way is manufactured by the manufacturing process which used the lead frame.

Next, the lead frame used for manufacture of a semiconductor device is explained using FIG. 5 ((a), (b)). The actual lead frame has multiple connection structure so that a plurality of semiconductor devices can be manufactured, but in order to make a drawing legible, FIG. 5 shows the region for one piece by which one semiconductor device is manufactured.

As shown in FIG. 5 ((a), (b)), lead frame LF has the structure which has arranged superficially a plurality of lead (A1, A2, B1, B2) 5, supporting body (6, 7), wire connecting part 6a, a plurality of suspension leads 8, resin molding regions 17, etc. to product formation area 16 divided with frame body 15 including outer frame 15a, inner frame 15b, etc.

In resin molding region 17, the plane is formed with rectangular form, for example. In resin molding region 17, one long side corresponds with under surface 12y of resin sealing body 12, the long side of another side corresponds with upper surface 12x of resin sealing body 12, and two short sides correspond with side surface 12z of resin sealing body 12.

As for supporting body 6, the plane is formed with rectangular shape, for example, and it is arranged in resin molding region 17. Each of a plurality of leads (A1, A2, B1, B2) 5 has inner part 5a located inside resin molding region 17, and outer part 5b located in the outside of resin molding region 17, and is extending and existing continuing within and without resin molding region 17. Lead (A1, A2) 5 is arranged at the outside of one long side of supporting body 6, and is crossing one long side of resin molding region 17. Lead (B1) 5 is arranged at the outside of one short side of supporting body 6, and is crossing the long side of another side of resin molding region 17. Lead (B2) 5 is arranged at the outside of the short side of another side of supporting body 6, and is crossing the long side of another side of resin molding region 17. Supporting body 7 is arranged at the outside of one long side of supporting body 6, and between lead (A1) 5 and lead (A2) 5 in resin molding region 17. Wire connecting part 6a is arranged at the outside of the short side of supporting body 6, and in resin molding region 17.

Here, if condenser 4 is only mounted in back surface 6y of supporting body 6, electrode 4b of condenser 4 and supporting body 7 which connects electrode 4b of condenser 4 electrically may be arranged to the upper surface 12x side of resin sealing body 12. However, what is necessary is just to make the distance of firing circuit 24 and firing element 34 approach as much as possible, in order to detect a collision and to light gunpowder 38 promptly with firing to ignition device 30 based on the signal transmitted from electronic control unit 40. As for firing circuit 24, since firing element 34 is mounted in upper surface 12x of resin sealing body 12 in Example 1, it is preferred to arrange to the side of long side located in the upper surface 12x side of resin sealing body 12 in semiconductor chip 2. This mounts electrode 4a for outputting the power supply potential from condenser 4 so that it may be located in the upper surface 12x side of resin sealing body 12 rather than electrode 4b for inputting the power supply potential supplied from controlling circuit 20.

Supporting body 6 is connected with frame body 15 (inner frame 15b) in one via four suspension leads 8, supporting body 7 is connected with frame body 15 (inner frame 15b) in one via two suspension leads 8, and, as for a plurality of leads (A1, A2, B1, B2) 5, each outer part 5b is connected with frame body 15 (inner frame 15b) in one.

Lead frame LF constituted in this way is manufactured by performing etching processing or press working to the plate material which includes the alloy of an iron (Fe)-nickel system, copper (Cu), or alloy of a Cu system, for example, and forming a predetermined lead pattern in it. Therefore, each portion (lead 5, supporting body 6, wire connecting part 6a, supporting body 7) of lead frame LF has the main surface and back surface which are mutually located in the opposite side, and the main surface of each portion is located in a same side in the thickness direction of lead frame LF.

Inner frame 15b functions in a resin molding step as a dam bar for damming up the resin which leaks from between leads 5.

Next, manufacture of semiconductor device 1 using a lead frame is explained using FIG. 6 through FIG. 14.

First, lead frame LF shown in FIG. 5, and semiconductor chip 2 shown in FIG. 2 and condenser 4 are prepared.

Next, paste state binding material 9 is applied to main surface 6x of supporting body 6 at the main surface side of lead frame LF (<101> step of FIG. 6). The application of binding material 9 is performed, for example by a dispensing method. As binding material 9, the Ag paste material by which a plurality of Ag particles were mixed in the thermosetting resin of an epoxy system or a polyimide system, for example is used.

Next, as shown in FIG. 7 ((a), (b)), semiconductor chip 2 is mounted via binding material 9 at the main surface side of lead frame LF on main surface 6x of supporting body 6 (<102> step of FIG. 6). Semiconductor chip 2 is mounted in the condition that the back surface of semiconductor chip 2 faces main surface 6x of supporting body 6.

Next, baking processing for curing paste state binding material 9 is performed (<103> step of FIG. 6). Adhesion fixing of the semiconductor chip 2 is performed to main surface 6x of supporting body 6 via binding material 9 by this step.

Next, in the main surface of lead frame LF as shown in FIG. 8 ((a), (b)), a plurality of electrode pads 3 of semiconductor chip 2, and inner part 5a of a plurality of leads (A1, A2, B1, B-2) 5, supporting body 7 and wire connecting part 6a are electrically connected by a plurality of bonding wires 10 (<104> step of FIG. 6).

As for bonding wire 10 which connects electrically electrode pad p1, p2, p5, p6, and lead A1, A2, B1 and B2, respectively, the one end side is connected to electrode pad (p1, p2, p5, p6) 3, and the other end side is connected to the main surface of inner part 5a of lead (A1, A2, B1, B2) 5. As for bonding wire 10 which connects electrically electrode pad p3 and supporting body 7, the one end side is connected to electrode pad (p3) 3, and the other end side is connected to main surface 7x of supporting body 7. As for bonding wire 10 which connects electrically electrode pad (p4) 3 and wire connecting part 6a, the one end side is connected to electrode pad p4, and the other end side is connected to the main surface of wire connecting part 6a.

In a plurality of lead 5, supporting bodies 6 and 7, and wire connecting parts 6a, in order to aim at improvement in a bondability with bonding wire 10, Ag plating is performed in the portion to which bonding wire 10 is connected.

Next, after reversing the back and front of lead frame LF, in the back surface of lead frame LF, paste state binding material 11 is applied to back surface 6y of supporting body 6, and back surface 7y of supporting body 7, respectively (<105> step of FIG. 6). The application of binding material 11 is performed, for example by a dispensing method. As binding material 11, paste state lead free solder material (for example, solder material of Au—Sn composition) is used, for example. Since the volume (mass) of condenser 4 is larger than semiconductor chip 2, about adhesion with a supporting body, condenser 4 is lower. However, compared with the case where binding material 9 for mounting semiconductor chip 2 which includes Ag paste material is used, adhesion can be improved by mounting condenser 4 with binding material 11 which includes lead free solder material. In order to secure the electrical property of condenser 4 and supporting bodies 6 and 7, the material which has conductivity is used for binding material 11. Although the solder of Sn-37[wt %]Pb composition may mainly be used for manufacture of a semiconductor device, the measures against environmental protection are possible by using lead free solder like Example 1.

Next, in the back surface of lead frame LF, as shown in FIG. 9 ((a), (b)), condenser 4 is mounted via binding material 11 on each back surface of supporting body 6 and 7 (<106> step of FIG. 6). Condenser 4 is mounted in the condition that electrode 4a faces back surface 6y of supporting body 6, and electrode 4b faces back surface 7y of supporting body 7.

Next, reflow treatment for fusing paste state binding material 11 is performed (<107> step of FIG. 6), and melted binding material 11 is cured after that. Adhesion fixing of the electrode 4a of condenser 4 is performed to back surface 6y of supporting body 6 via binding material 11, adhesion fixing of the electrode 4b of condenser 4 is performed to back surface 7y of supporting body 7 via binding material 11 by this step, and they are connected electrically and mechanically.

Next, as shown in FIG. 10 and FIG. 11, resin molding of semiconductor chip 2, condenser 4, inner part 5a of a plurality of leads 5 (A1, A2, B1, B-2), a supporting body (6, 7), a plurality of bonding wires 10, etc. is performed, and resin sealing body 12 is formed (<108> step of FIG. 6). Formation of resin sealing body 12 is performed by the transfer molding method for having used the thermosetting resin of an epoxy system, for example.

In this step, resin sealing body 12 is formed in the cylinder shape whose upper surface 12x and under surface 12y which are mutually located in the opposite side become from a plane, and whose side surface 12z becomes from a curved surface and plane 12a. As each main surface is situated along the height direction (Z direction) of resin sealing body 12, resin molding of semiconductor chip 2, supporting bodies 6 and 7, and a plurality of leads 5 is performed.

Next, as shown in FIG. 12, marking of the distinguishing mark 19 which displays information, including a name of article, a company name, a kind, a manufacture lot number, etc., on plane 12a in the side surface of resin sealing body 12 is performed for example, by the laser marking method (<109> step of FIG. 6).

Next, lead frame LF and unnecessary resin are cut, and as shown in FIG. 13, lead 5 is separated from frame body 15 (<110> step of FIG. 6).

Next, Ni plating treatment is performed to outer part 5b of lead 5 (<111> step of FIG. 6).

Next, as shown in FIG. 14, predetermined shape is formed by processing bending to outer part 5b of lead 5 (<112> step of FIG. 6). In this step, outer part 5b of lead 5 is formed by the shape which has first portion 5b1 and second portion 5b2.

Next, suspension lead 8 is cut (<113> step of FIG. 6). According to this step, semiconductor device 1 shown in FIG. 1 through FIG. 4 is completed mostly.

Next, the ignition device having semiconductor device 1 is explained using FIG. 15 through FIG. 19.

Ignition device 30 has package structure which built in semiconductor device (package) 1, firing element 34, gunpowder 38, etc. in the cavity formed by case (casing) 31 and header 32, as shown in FIG. 15 ((a), (b)) and FIG. 16 ((a), (b)). Case 31 is formed with the cylindrical shape which has a bottom face, and header 32 is inserted and fixed so that opening of case 31 may be plugged up.

As shown in FIG. 16 ((a), (b)), two through holes are formed in header 32, and the end side of a lead pin (33a, 33b) is being inserted and fixed to it by these two through holes via the insulating material, respectively. As shown in FIG. 20, one lead pin 33a is connected to one bus 42a (Bus-A), and lead pin 33b of another side is connected to bus 42b (Bus-B) of another side.

The tip at the side of the end of lead pin 33a is, at outer part 5b of lead (A1) 5 which projects from the bottom face of resin sealing body 12 of semiconductor device 1, contacted by second portion 5b2 bent in the direction (direction parallel to under surface 12y of sealing body 12) along under surface 12y of resin sealing body 12, and connects electrically mutually. The tip at the side of the end of lead pin 33b is, at outer part 5b of lead (A2) 5 which projects from the bottom face of resin sealing body 12 of semiconductor device 1, contacted by second portion 5b2 bent in the direction (direction parallel to under surface 12y of sealing body 12) along under surface 12y of resin sealing body 12, and connects electrically mutually.

Firing element 34 is arranged on upper surface 12x of resin sealing body 12. Firing element 34 has the structure of having two electrodes (35a, 35b), and resistor 36 (firing part) which is arranged between these two electrodes (35a, 35b), and is connected with these two electrodes (35a, 35b) in one on the main surface of a substrate, as shown in FIG. 18. Two electrodes (35a, 35b) and resistor 36 are formed with the electric conduction thin film. Resistance 36 generates heat by supplying power supply potential to two electrodes (35a, 35b). The width of the Y direction in resistor 36 is narrower than the width of the Y direction of two electrodes (35a, 35b).

One electrode 35a of firing element 34 is electrically connected with outer part 5b of lead (B1) 5 which projects from upper surface 12x of resin sealing body 12 of semiconductor device 1 via bonding wire 37, and electrode 35b of another side of firing element 34 is electrically connected with outer part 5b of lead (B2) 5 which project from upper surface 12x of resin sealing body 12 of semiconductor device 1 via bonding wire 37. As for bonding wire 37 which connects electrically one electrode 35a of firing element 34, and outer part 5b of lead (B1) 5, the one end side is connected to electrode pad 35a, and the other end side is connected to second portion (terminal for external connection) 5b2 bent in the direction (the Y direction, a direction vertical to the height direction of resin sealing body 12) which is along upper surface 12x of resin sealing body 12 in outer part 5b of lead (B1) 5. As for bonding wire 37 which connects electrically electrode 35b of another side of firing element 34, and outer part 5b of lead (B2) 5, the one end side is connected to electrode pad 35b, and the other end side is connected to second portion (terminal for external connection) 5b2 bent in the direction (the Y direction, a direction vertical to the height direction of resin sealing body 12) which is along upper surface 12x of resin sealing body 12 in outer part 5b of lead (B2) 5.

As bonding wire 37, the Al wire is used, for example. The ultrasonic wedge-bonding (wedge bonding) method using supersonic vibration for example as a connection method of bonding wire 37 is used.

Gunpowder 38 is filled up between the bottom face of case 31 and upper surface 12x of resin sealing body 12 as shown in FIG. 16, and resistor 36 of firing element 34 is covered by gunpowder 38.

Although not limited to this, the assembly of ignition device 30 is carried out by preparing semiconductor device 1, case 31, firing element 34, gunpowder 38, and header 32 in which the lead pin (33a, 33b) was formed, then, connecting (for example, soldering connection) the input terminal for external connection (second portion 5b2) which includes outer part 5b of lead (A1, A2) 5 of semiconductor device 1, and the tip part of the lead pin (33a, 33b) of header 32, then, adhering firing element 34 on upper surface 12x of resin sealing body 12 of semiconductor device 1, then, electrically connecting the electrode (35a, 35b) of firing element 34 and the output terminal for external connection (second portion 5b2) which includes outer part 5b of lead (B1, B2) 5 of a semiconductor device by bonding wire 37, then, inserting firing element 34, semiconductor device 1, and header 32 in case 31 with which gunpowder 38 was formed in the bottom face sequentially from the firing element 34 side, then, adhering case 31 and header 32. Namely, as for firing element 34, semiconductor device 1 having semiconductor chip 2 and condenser 4, and header 32 with a lead pin, each is constituted as components of another object, and ignition device 30 is manufactured by assembling these components.

As shown in FIG. 17, ignition device 30 has the structure which has arranged gunpowder 38, firing element 34, semiconductor device 1, header 32, and the lead pin (33a, 33b) one by one from the bottom-face side of case 31. Gunpowder 38 and firing element 34 are arranged at the upper surface 12x side of resin sealing body 12, and header 32 and the lead pin (33a, 33b) are arranged at the under surface 12y side of resin sealing body 12. That is, semiconductor chip 2 and condenser 4 which were built in semiconductor device 1 are arranged on the straight line which ties virtually firing element 34 and a lead pin (33a, 33b). Semiconductor chip 2 and condenser 4 are arranged so that each thickness direction (the Y direction) may be situated along the direction (the Y direction) which crosses the height direction (Z direction) of case 31 at right angles.

Semiconductor device 1 is arranged as side surface 12z of resin sealing body 12 touches the inner wall surface of case 31. Although resin sealing body 12 has plane 12a on a part of side surface 12z, this plane 12a is spaced out from the inner wall surface of case 31, and is not in contact with an inner wall surface.

Next, the operation procedures at the time of protective-gear diagnosis and the operation procedures at the time of a collision of an airbag system are explained using FIG. 19, and FIG. 24 through FIG. 27. The power supply superimposition system (one cable system) which also supplies a signal to Bus-A (42a) or Bus-B (42b) together with a power source is used for an airbag system. Therefore, the non-polarization which does not have an electrode (+/−) is aimed at, and Bus-A and Bus-B serve as positioning to two LAN wiring which either called the “main” and another side called “recovery” among Bus-A and B. Although Bus-B (42b) is functioning as reference potential (GND, Vss) in the embodiment, since the non-polarization is aimed at as mentioned above, when Bus-B is operating as main, Bus-A (42a) functions as reference potential (GND, Vss).

First, the operation procedures at the time of protective-gear diagnosis are explained using FIG. 19, FIG. 24, and FIG. 25.

First, if ignition is turned ON<201>, electronic control unit (protective-gear diagnostic ECU) 40 will supply a check instruction signal and a power source (charge) to ASRB driver 22 of controlling circuit 20 mounted in semiconductor chip 2 <202>. Feeding of this check instruction signal and charge is carried out via electric conduction path-A including bus (Bus-A) 42a, lead pin 32a, lead (A1) 5, bonding wire 10, and electrode pad (p1) 3, or electric conduction path-B including bus (Bus-B) 42b, lead pin 32b, lead (A2) 5, bonding wire 10, and electrode pad (p2) 3. Electronic control unit 40 turns ON an indicator <202A>.

ASRB driver 22 receives the check instruction signal and power source from electronic control unit 40 <203>, and transmits a check instruction signal to controller 21.

Controller 21 transmits a check instruction to diagnosing circuit 25, firing circuit 24, and power supply circuit 23 based on the check instruction signal from ASRB driver 22 <204>.

Firing circuit 24 checks a circuit and a firing element (heating element) 34 based on the command of controller 21, and transmits a checked result to diagnosing circuit 25 <206>. Power supply circuit 23 supplies a power source (charge) to condenser 4 based on the command of controller 21 <207>. Condenser 4 receives charge from power supply circuit 23 <207A>. Diagnosing circuit 25 checks a circuit, and the charging state of condenser 4, and transmits a checked result to controller 21 <205>.

Controller 21 receives the checked result from diagnosing circuit 25 <208>, and transmits this checked result to ASRB driver 22. ASRB driver 22 receives the checked result from controller 21 <209>, and transmits this checked result to electronic control unit 40. Transmission of a checked result is performed via electric conduction path-A or B.

Electronic control unit 40 receives the checked result from ASRB driver 22 <210>. When a checked result is O. K., an OK signal is transmitted to electronic control unit 40, and an indicator is set to off <211>. When a checked result is NG, NG signal is transmitted to electronic control unit 40, and an indicator is set to ON<202A>.

Next, the operation procedures at the time of a collision are explained using FIG. 19, FIG. 26, and FIG. 27.

First, impact detection sensor 41 detects an impact and transmits a signal to electronic control unit 40 <301>. Based on the signal from impact detection sensor 41, electronic control unit 40 judges target ignition device (squib) 30 <302>, and transmits an initiation signal to ASRB driver 22 of target ignition device 30 <303>. Transmission of this initiation signal is performed via electric conduction path-A or B.

ASRB driver 22 receives an initiation signal and transmits this initiation signal to controller 21 <304>. Controller 21 receives an initiation command and transmits an initiation command to firing circuit 24 <305>. Firing circuit 24 receives an initiation command <306> and supplies the charge of condenser 4 to firing element 34 based on an initiation command <307>. By charge feeding from condenser 4, resistor 36 of firing element 34 generates heat, and gunpowder 38 is lit <308>. With firing to ignition device 30 by firing of gunpowder 38, an air bag (air bag device 50) and pretensioner 57 operate. Pretensioner 57 is a device which winds up a seat belt about 10 cm, for example.

In Example 1, semiconductor device 1 has the package structure which used lead frame LF. Generally, the adhesion of a lead frame and the resin for sealing (mold resin) is higher than the adhesion of a wiring substrate and the resin for sealing. This originates in the coefficient-of-linear-expansion difference of a lead frame and the resin for sealing being smaller than the coefficient-of-linear-expansion difference of a wiring substrate and the resin for sealing. Therefore, since adhesion with the resin for sealing can be secured and stress reduction can be aimed at also in the severe heat cycle test for automobiles of a service condition by using the package structure using a lead frame in semiconductor device 1 having semiconductor chip 2 (device for communication) on which controlling circuit 20 is mounted, and condenser 4 for firing like Example 1, peeling of the resin for sealing can be suppressed. As a result, improvement in reliability of semiconductor device 1 can be aimed at, and improvement in reliability of ignition device 30 having semiconductor device 1 can also be aimed at. When using a lead frame, since the wiring of a wiring pattern is unnecessary, compared with a wiring substrate, a manufacturing process is easy. Thereby, compared with the case where a wiring substrate is used, product cost can be made cheap.

Semiconductor device 1 has double-sided mounting structure which adhered semiconductor chip 2 on main surface 6x of supporting body 6, and adhered condenser 4 on back surface 6y of supporting body 6. That is, double-sided mounting of semiconductor chip 2 and the condenser 4 is performed at lead frame LF. With such double-sided mounting structure, in contrast to an one side parallel layout, reduction of a mounting area can be aimed at, the miniaturization of semiconductor device 1 is attained, and it can contribute also to the space saving (miniaturization) of ignition-device 30 itself.

In the case of the package structure using lead frame LF, it can respond to the terminal pitch, connection method, etc. which matched the customer's usage by changing a cutting part in the lead cutting step shown in FIG. 13, and changing forming shape in the lead forming step shown in FIG. 14.

In Example 1, as shown in FIG. 6, FIG. 8, and FIG. 9, semiconductor chip 2 was adhered on main surface 6x of supporting body 6 via binding material 9, after that, the back and front of lead frame LF was reversed, and condenser 4 is adhered on back surface 6y of supporting body 6, and back surface 7y of supporting body 7 via binding material 11, respectively. Thermosetting resin is used as binding material 9, and lead free solder is used as binding material 11. Thermosetting resin is not remelted once it hardens. Therefore, even if it melts paste state binding material 11 and adheres condenser 4 on each back surface (6y, 7y) of supporting bodies 6 and 7, since binding material 9 is not melted, it can suppress falling of semiconductor chip 2 pasted up previously. Therefore, the package structure that semiconductor chip 2 is pasted on main surface 6x of supporting body 6, and condenser 4 is adhered on back surface 6y of supporting body 6 (double-sided mounting to a lead frame), and suitable semiconductor device 1 for a miniaturization can be manufactured.

Falling of semiconductor chip 2 can be suppressed also when using the lead free solder whose fusing point is higher than binding material 11 as binding material 9. When the same material (the same fusing point) is used for this as a binding material carrying semiconductor chip 2 and condenser 4, when melting the binding material at the side of the condenser mounted later about semiconductor chip 2 which performed adhesion fixing previously, the binding material at the side of semiconductor chip 2 will melt again with the melt temperature, and semiconductor chip 2 will be falling from supporting body 6. However, since lead free solder has the high fusing point as compared with the solder of Pb—Sn composition, it is difficult to give a temperature hierarchy to binding material 9 and binding material 11. Therefore, as for adhesion of semiconductor chip 2, it is desirable like Example 1 to carry out using binding material 9 which includes thermosetting resin.

As shown in FIG. 2 and FIG. 3, in Example 1, electrode pad (p4) 3 of semiconductor chip 2 is connected with wire connecting part 6b electrically via bonding wire 10, wire connecting part 6b is formed in one with supporting body 6, and one electrode 4a of condenser 4 is electrically connected with supporting body 6. That is, supporting body 6 is used as an electric conduction path for connecting electrically electrode pad (p4) 3 of semiconductor chip 2, and one electrode 4a of condenser 4. Therefore, in order to connect electrically the electrode (4a, 4b) of condenser 4, and supporting bodies 6 and 7, solder material electrically conductive as binding material 11 is used. In order to perform insulated isolation of the back surface of semiconductor chip 2, and the supporting body 6 electrically, an insulating binding material is used as binding material 9. However, if controlling circuit 20 is electrically separated to the semiconductor substrate which is a base of semiconductor chip 2, an electrically conductive binding material can also be used. In Example 1, Ag paste material is used as binding material 11. Therefore, as for semiconductor chip 2 of Example 1, the semiconductor substrate and controlling circuit 20 are separated electrically. As a method of using a binding material electrically conductive as binding material 9, there is the method of covering the back surface of semiconductor chip 2 with the insulating film etc.

In Example 1, as shown in FIG. 6, FIG. 8, and FIG. 9, the step which mounts condenser 4 is carried out after a wire bonding step. At a wire bonding step, in order to increase the reliability of wire bonding, the wire bonding method which used supersonic vibration together is used for thermo compression bonding. It is necessary to heat semiconductor chip 2 by this wire bonding method. Heating of semiconductor chip 2 is performed by contacting back surface 6y of supporting body 6 to a bonding stage (heat stage), and heating supporting body 6 with a bonding stage. Since condenser 4 interferes when a wire bonding step is carried out after the mounting step of condenser 4, it becomes difficult to contact back surface 6y of supporting body 6 to a bonding stage. Therefore, since heating and supersonic vibration can be added to semiconductor chip 2 by carrying out a wire bonding step like Example 1 before the step which mounts condenser 4, the reliability of wire bonding can be increased and improvement in reliability of semiconductor device 1 which has the package structure which performed double-sided mounting of semiconductor chip 2 and the condenser 4 in supporting body 6 can be aimed at.

In Example 1, two wire connecting parts 6a are formed, and the charge feed route which ties firing circuit 24 and supporting body 6 has become two lines. At the time of a collision, the charge of condenser 4 is supplied to firing circuit 24 by said two charge feed routes, and is supplied to firing element 34 via this firing circuit 24. Thus, since the charge of condenser 4 can be supplied to firing circuit 24 in the charge feed route of another side even if one charge feed route is disconnected under a certain effect by forming two charge feed routes, gunpowder 38 of ignition device 30 can be surely lit at the time of a collision. Therefore, improvement in reliability of semiconductor device 1 of double-sided mounting structure can be aimed at, and improvement in reliability of ignition device 30 which contains this semiconductor device 1 further can be aimed at. In Example 1, although two charge feed routes were explained, if the disposition space of wire connecting part 6a is securable, a charge feed route is good as for three or more lines.

In Example 1, as shown in FIG. 1, resin sealing body 12 of semiconductor device 1 is cylinder shape, and has the structure of having plane 12a in a part of side surface 12z. At the marking step shown in FIG. 12, marking of the distinguishing mark 19 is performed to plane 12a of side surface 12z. Plane one can perform marking surely easily rather than a curved surface. Therefore, since poor marking can be reduced even if it is semiconductor device 1 which comprised cylinder-shaped resin sealing body 12, improvement in the yield of cylinder-shaped semiconductor device 1 can be aimed at.

In Example 1, plane 12a in side surface 12z of resin sealing body 12 is formed spacing out from upper surface 12x of resin sealing body 12, as shown in FIG. 4. If semiconductor device 1 of such package structure is incorporated in case 31 of ignition device 30, as shown in FIG. 17, plane 12a in side surface 12z of resin sealing body 12 will be spaced out from the inner wall surface of case 31, and will not touch an inner wall surface. That is, in resin sealing body 12, the side surface of 12N (refer to FIG. 4) of upper part comprising upper surface 12x contacts the inner wall surface of case 31 about the all perimeter, and the side surface of lower part 12M (refer to FIG. 4) comprising under surface 12y and plane 12a contacts the inner wall surface of case 31 except for the portion of plane 12a. Therefore, since 12N of upper part of resin sealing body 12 serve as a partition by forming plane 12a spacing out from upper surface 12x of resin sealing body 12 in a part of side surface 12z of resin sealing body 12, gunpowder 38 on upper surface 12x of resin sealing body 12 does not move to the header 32 side. Therefore, even if plane 12a is formed in side surface 12z of resin sealing body 12 in consideration of marking nature, the defective ignition by the filling failure of gunpowder 38 in upper surface 12x of resin sealing body 12 can be prevented.

In Example 1, as shown in FIG. 17, ignition device 30 has structure which has arranged gunpowder 38, firing element 34, semiconductor device 1, header 32, and the lead pin (33a, 33b) one by one from the bottom-face side (bottom side) of case 31. Gunpowder 38 and firing element 34 are arranged at the upper surface 12x side of resin sealing body 12, and header 32 and the lead pin (33a, 33b) are arranged at the under surface 12y side of resin sealing body 12. That is, semiconductor chip 2 and condenser 4 which were built in semiconductor device 1 are arranged on the straight line which ties virtually firing element 34 and a lead pin (33a, 33b). Semiconductor chip 2 and condenser 4 are arranged so that each thickness direction (the Y direction) may be situated along the direction (the Y direction) crossing the height direction (Z direction) of case 31 at right angles. Since the electric conduction path which ties firing element 34 and a lead pin (33a, 33b) by having such structure can be shortened, thinning of ignition device 30 can be aimed at.

In Example 1, outer part 5b of lead (A1, A2) 5 which projects from under surface 12y of resin sealing body 12 has the structure of having second portion 5b2 bent in the direction along under surface 12y of resin sealing body 12, as shown in FIG. 17. Since the area of the terminal for external connection at the side of under surface 12y of resin sealing body 12 becomes large by having such structure, in the assembly of ignition device 30, the faulty connection of lead 5, and the lead pin of header 32 (33a, 33b) of semiconductor device 1 can be reduced. Hereby, improvement in a manufacturing yield of ignition device 30 can be aimed at.

Outer part 5b of lead (B1, B2) 5 which projects from upper surface 12x of resin sealing body 12 has the structure of having second portion 5b2 bent in the direction along upper surface 12x of resin sealing body 12, as shown in FIG. 17. In the assembly of ignition device 30, firing element 34 is arranged on the upper surface 12x of resin sealing body 12, and outer part 5b of lead (B1, B2) 5 of a semiconductor device and the electrode (35a, 35b) of firing element 34 are electrically connected via bonding wire 37. Like Example 1, since bending processing is performed to outer part 5b, the electrode (35a, 35b) surface of firing element 34 and the surface of second portion 5b2 become parallel. The area of a bonding part becomes large by bending processing. By this, since bondability improves, wire faulty connection can be suppressed, and improvement in a manufacturing yield of ignition device 30 can be aimed at.

In Example 1, as bonding wire 10 which connects electrically electrode pad 3 of semiconductor chip 2, and the connecting part (lead 5, supporting body 7, wire connecting part 6a) arranged to the perimeter, Au wire is used and the Al wire is used as bonding wire 37 which connects electrically outer part 5b of lead (B1, B2) 5 of semiconductor device 1, and the electrode (35a, 35b) of firing element 34. Compared with Au wire, mechanical strength of an Al wire is high. On the other hand, as to the assembly of ignition device 30, semiconductor device 1 having firing element 34 by which wire bonding was performed on the upper surface 12x of resin sealing body 12 is pushed in into case 31 with which gunpowder 38 is filled up by the bottom face (bottom). Therefore, deformation of wire 37 at the time of the assembly of ignition device 30 can be suppressed by using an Al wire as bonding wire 37. Hereby, improvement in reliability of ignition device 30 can be aimed at.

Since the lead frame of a whole surface Ni plating article can be used if both can use an Al wire, the plating step in a post-process can be skipped. However, the binding material used for adhesion of semiconductor chip 2 in this case is generally the solder (or Pb free solder) with strong adhesive strength and composition strength which can bear the supersonic wave at the time of W/B. In Example 1, the Ag paste which can endure heating at the time of condenser 4 mounting is being used for the binding material of semiconductor chip 2 in order to enable lead frame double-sided mounting. Ag paste is not remelted, but while it is strong with heat, as compared with solder etc., adhesive strength and composition strength are weak, and we are anxious about the ability not to bear the ultrasonic power at the time of bonding of an Al wire. Therefore, Ag plating is performed to the wire connecting part of a lead frame, and Au wire is used for the wire of semiconductor chip 2.

Because of sealing semiconductor device 1 and gunpowder 38 by the assembly of ignition device 30, applying high pressure into case 30, when both use Au wire conversely, a disconnection failure after sealing is expected with Au wire.

Since it will become a high cost if Au wire is made thick, the Al wire which is cheap and effective for electric supply and in which a wire diameter can be made thick is used for the firing element 34 side.

### EXAMPLE 2

FIG. 28 is a schematic sectional view showing the internal structure of the ignition device which is an Example 2 of the present invention.

As shown in FIG. 28, plane 12a formed in side surface 12z of resin sealing body 12 is continued and formed in under surface 12y from upper surface 12x of resin sealing body 12. Hereby, the design of the metal mold which forms resin sealing body 12 can be simplified. In such a case, gunpowder 38 at the side of upper surface 12x of resin sealing body 12 will move to the header 32 side. So, in Example 2, divider plate 39 which prevents movement of gunpowder 38 is formed in the upper surface 12x side of resin sealing body 12. Divider plate 39 is formed in the shape to which the side surface contacts the inner wall surface of case 31, and opening is formed in the central part. Divider plate 39 is arranged around firing element 34 so that firing element 34 may be exposed from the opening.

Thus, even if it is plane 12a continued and formed in under surface 12y from upper surface 12x of resin sealing body 12 by forming divider plate 39, movement of gunpowder 38 can be suppressed.

As things mentioned above, the present inventions accomplished by the present inventors were concretely explained based on above embodiments, but the present inventions are not limited by above embodiments, but variations and modifications may be made, of course, in various ways in the limit that does not deviate from the gist.

### INDUSTRIAL APPLICABILITY

The present invention is applicable to the ignition device used for the airbag system of a bus-connection method, and the semiconductor device built in it.

1. A semiconductor device, comprising:
a semiconductor chip which has a main surface and a back surface which are mutually located in an opposite side, and a plurality of electrode pads arranged over the main surface;
a capacitative element which has a first and a second electrode;
a supporting body which has a main surface and a back surface which are mutually located in an opposite side;
a plurality of leads arranged around the supporting body;
a plurality of bonding wires which connect electrically the electrode pads of the semiconductor chip, and the leads; and
a resin sealing body which seals the semiconductor chip, the capacitative element, the supporting body, the leads, and the bonding wires;
wherein
the leads extend and exist continuing in and out of the resin sealing body;
the semiconductor chip is adhered over the main surface of the supporting body; and
the capacitative element is adhered over the back surface of the supporting body.

2. A semiconductor device, comprising:
a semiconductor chip which has a main surface and a back surface which are mutually located in an opposite side, and a controlling circuit and a plurality of electrode pads which have been arranged in the main surface;
a capacitative element which has a first and a second electrode;
a first supporting body that has a main surface and a back surface which are mutually located in an opposite side;
a second supporting body that is the second supporting body arranged around the first supporting body, and has a main surface and a back surface which are mutually located in an opposite side, and with which the main surface is located in a same side as the main surface of the first supporting body in a thickness direction of the first supporting body;
a plurality of leads arranged around the first supporting body;
a plurality of bonding wires which connect electrically the electrode pads of the semiconductor chip, and the leads, and the main surface of the second supporting body; and
a resin sealing body which seals the semiconductor chip, the capacitative element, the first and the second supporting body, the leads, and the bonding wires;
wherein
the leads extend and exist continuing in and out of the resin sealing body;
the semiconductor chip is adhered over the main surface of the first supporting body;
the first electrode of the capacitative element is adhered over the back surface of the first supporting body; and
the second electrode of the capacitative element is adhered over the back surface of the second supporting body.

3. A semiconductor device, comprising:
a semiconductor chip which has a main surface and a back surface which are mutually located in an opposite side, and a controlling circuit and a plurality of electrode pads which have been arranged in the main surface;
a capacitative element which has a first and a second electrode;
a first supporting body that has a main surface and a back surface which are mutually located in an opposite side;
a second supporting body that is the second supporting body arranged around the first supporting body, and has a main surface and a back surface which are mutually located in an opposite side and with which the main surface is located in a same side as the main surface of the first supporting body in a thickness direction of the first supporting body;
a wire connecting part which is arranged around the first supporting body and connects with the first supporting body;
a plurality of leads arranged around the first supporting body;
a plurality of bonding wires which connect electrically the electrode pads of the semiconductor chip, and the leads, the wire connecting part and the main surface of the second supporting body; and
a resin sealing body which seals the semiconductor chip, the capacitative element, the first and the second supporting body, the wire connecting part, the leads, and the bonding wires;
wherein
the leads extend and exist continuing in and out of the resin sealing body;
the semiconductor chip is adhered over the main surface of the first supporting body;
the first electrode of the capacitative element is adhered over the back surface of the first supporting body; and
the second electrode of the capacitative element is adhered over the back surface of the second supporting body.

4. A semiconductor device according to any one of claims 1-3, wherein
the resin sealing body has an upper surface, an under surface, and a side surface; and
the leads have a first lead that projects from the under surface of the resin sealing body, and a second lead that projects from the upper surface of the resin sealing body.

5. A semiconductor device according to claim 4, wherein
the first and the second lead has an inner part located in an inside of the resin sealing body, and an outer part located in an outside of the resin sealing body;
the outer part of the first lead has a first portion that projects from the under surface of the resin sealing body, and a second portion that bends in a direction along the under surface of the resin sealing body from the first portion; and
the outer part of the second lead has a first portion that projects from the upper surface of the resin sealing body, and a second portion that bends in a direction along the upper surface of the resin sealing body from the first portion.

6. A semiconductor device according to claim 5, wherein
the second portion of the first lead has a portion of width wider than the first portion of the first lead; and
the second portion of the second lead has a portion of width wider than the first portion of the second lead.

7. A semiconductor device according to any one of claims 1-3, wherein
the supporting body is arranged as the main surface of the supporting body is situated along a height direction of the resin sealing body.

8. A semiconductor device according to any one of claims 1-3, wherein
the resin sealing body is formed in a cylinder shape which has an upper surface and an under surface including a plane, and a side surface including a curved surface.

9. A semiconductor device according to any one of claims 1-3, wherein
the resin sealing body is formed in a cylinder shape which has an upper surface and an under surface including a plane, and a side surface including a curved surface; and
the side surface of the resin sealing body has a plane in part.

10. A semiconductor device according to any one of claims 1-3,
wherein
the resin sealing body is formed in a cylinder shape which has an upper surface and an under surface including a plane, and a side surface including a curved surface; and
the side surface of the resin sealing body has a plane spaced out from the upper surface of the resin sealing body in part.

11. A semiconductor device according to claim 2 or 3, wherein
the semiconductor chip is adhered over the first supporting body via a first binding material;
the capacitative element is adhered over the first and the second supporting body via a second binding material; and
the first binding material includes material whose fusing point is higher than the second binding material.

12. A semiconductor device according to claim 2 or 3, wherein
the semiconductor chip is adhered over the first supporting body via a first binding material;
the capacitative element is adhered over the first and the second supporting body via a second binding material;
the first binding material includes a thermosetting material; and
the second binding material includes solder material.

13. A semiconductor device according to any one of claims 1-3, being built in an ignition device for mounting over a vehicle which operates an air bag based on a signal from an electronic control unit connected to an impact detection sensor.

14. A semiconductor device built in an ignition device for mounting over a vehicle which operates an air bag based on a signal from an electronic control unit connected to an impact sensor, comprising:
a semiconductor chip which has a main surface, a back surface which is an opposite side as the main surface, and a controlling circuit and a plurality of electrode pads formed over the main surface;
a capacitative element which has a first electrode and a second electrode;
a chip mounting part which has a first surface, and a second surface of an opposite side to the first surface;
a first through fourth lead that is a first through fourth lead arranged around the chip mounting part, and has a first surface and a second surface where each is mutually located in an opposite side, and with which the first surface is located in a same side as the first surface of the chip mounting part in a thickness direction of the chip mounting part;
a plurality of wires which connect electrically the electrode pads of the semiconductor chip, and each first surface of the first through fourth lead; and
a resin sealing body which seals the semiconductor chip, the capacitative element, the first through fourth lead, the wires, and the chip mounting part;
wherein
the first and the second lead extend and exist continuing in and out of the resin sealing body,
the semiconductor chip is arranged as facing the first surface of the chip mounting part; and
the capacitative element is arranged, as the first electrode of the capacitative element faces the second surface of the chip mounting part and the second electrode of the capacitative element faces the second surface of the third lead.

15. A semiconductor device according to claim 14, wherein
the first lead is a lead with which power supply potential is supplied and a control signal which controls the controlling circuit of the semiconductor chip is supplied;
the second lead is a lead which outputs a control signal supplied from the semiconductor chip based on the control signal;
the third lead is a lead with which power supply potential is supplied from the semiconductor chip; and
the fourth lead is a lead which supplies a power supply potential outputted from the capacitative element to the semiconductor chip.

16. A semiconductor device according to claim 14, wherein
the two first leads are formed, one side is an anode, and another side is a cathode.

17. A semiconductor device according to claim 14, wherein
the fourth lead is connected with the chip mounting part, and a plurality of fourth leads are formed.

18. A semiconductor device according to claim 14, wherein
the semiconductor chip is being fixed to the chip mounting part via a binding material.

19. A semiconductor device according to claim 18, wherein
the binding material includes an insulating material.

20. A semiconductor device according to claim 18, wherein
the binding material includes a conductive material, and the back surface of the semiconductor chip is insulated to the chip mounting part.

21. A semiconductor device according to claim 14, wherein
the first electrode of the capacitative element is electrically connected with the chip mounting part; and
the second electrode of the capacitative element is electrically connected with the third lead.

22. A semiconductor device according to claim 14, wherein
the capacitative element is being fixed to the chip mounting part via lead free solder.

23. A semiconductor device according to claim 22, wherein
the capacity of the capacitative element is 2.2□F.

24. A semiconductor device according to claim 14, wherein
the first lead and the second lead are mutually arranged bordering on the chip mounting part in a location of an opposite side.

25. A semiconductor device according to claim 14, wherein
the two first leads are formed; and
the third lead is formed between the first leads.

26. A semiconductor device according to claim 14, wherein
the fourth lead is arranged between the first lead and the second lead.

27. A semiconductor device according to claim 14, wherein
the resin sealing body has an upper surface, an under surface, and a side surface;
the chip mounting part and the first and the second lead are arranged along a height direction of the resin sealing body;
the first lead is projected from the under surface of the resin sealing body; and
the second lead is projected from the upper surface of the resin sealing body.

28. A semiconductor device according to claim 27, wherein
the first and the second lead has an inner part located in an inside of the resin sealing body, and an outer part located in an outside of the resin sealing body;
the outer part of the first lead has a first portion that projects from the under surface of the resin sealing body, and a second portion that bends in a direction along the under surface of the resin sealing body from the first portion; and
the outer part of the second lead has a first portion that projects from the upper surface of the resin sealing body, and a second portion that bends in a direction along the upper surface of the resin sealing body from the first portion.

29. A semiconductor device according to claim 28, wherein
Ag plating is performed to a portion of the inner part of each of the first and the second lead to which the wire is connected; and
Ni plating is performed to each second portion of the first and the second lead.

30. A semiconductor device according to claim 14, wherein
the wires are Au wires.

31. A semiconductor device according to claim 15, wherein
the two first leads are formed and one first lead supplies power supply potential lower than the first lead of another side.

32. A semiconductor device according to claim 15, wherein
the two second leads are formed and one second lead supplies power supply potential lower than the second lead of another side.

33. A manufacturing method of a semiconductor device, comprising the steps of:
(a) preparing a semiconductor chip which has a main surface and a back surface which are mutually located in an opposite side, and a controlling circuit and a plurality of electrode pads which have been arranged in the main surface;
(b) preparing a capacitative element which has a first electrode and a second electrode;
(c) preparing a lead frame which has a first supporting body that has a main surface and a back surface which are mutually located in an opposite side, and a plurality of leads with which each has an inner part and an outer part, and each of the inner part has been arranged around the supporting body;
(d) adhering the semiconductor chip over the main surface of the first supporting body via a first binding material;
(e) connecting electrically the electrode pads of the semiconductor chip, and each inner part of the leads by a plurality of bonding wires;
(f) adhering the first electrode of the capacitative element over the back surface of the first supporting body via a second binding material; and
(g) forming a resin sealing body by performing resin seal of the semiconductor chip, the first supporting body, each inner part of the leads, and the bonding wires.

34. A manufacturing method of a semiconductor device according to claim 33, wherein
the lead frame has further a second supporting body that is the second supporting body arranged around the first supporting body, and has a main surface and a back surface which are mutually located in an opposite side and with which the main surface is located in a same side as the main surface of the first supporting body in a thickness direction of the first supporting body; and
the second electrode of the capacitative element is adhered over the back surface of the second supporting body via the second binding material in the step (f).

35. A manufacturing method of a semiconductor device according to claim 33, wherein
the step (d) is carried out before the step (f); and
the first binding material includes material whose fusing point is higher than the second binding material.

36. A manufacturing method of a semiconductor device according to claim 33, wherein
the step (d) is carried out before the step (f);
the first binding material includes a thermosetting material; and
the second binding material includes solder material.

37. A manufacturing method of a semiconductor device according to claim 33, wherein
the step (f) is carried out after the step (e).

38. A manufacturing method of a semiconductor device according to claim 33, further comprising a step of bending and forming each outer part of the leads.

39. A manufacturing method of a semiconductor device according to claim 33, wherein
the resin sealing body is formed in a cylinder shape which has an upper surface and an under surface which includes a plane, and a side surface which includes a curved surface;
the leads have a first and a second lead;
as for the first lead, the outer part projects from the under surface of the resin sealing body; and
as for the second lead, the outer part projects from the upper surface of the resin sealing body.

40. A manufacturing method of a semiconductor device according to claim 33, wherein
the resin sealing body is formed in a cylinder shape which has an upper surface and an under surface including a plane, and a side surface including a curved surface; and
the first supporting body and the leads are arranged along a height direction of the resin sealing body.

41. A manufacturing method of a semiconductor device according to claim 33, wherein
the resin sealing body is formed in a cylinder shape which has an upper surface and an under surface including a plane, and a side surface including a curved surface.

42. An ignition device for mounting over a vehicle which operates an air bag based on a signal from an electronic control unit connected to an impact detection sensor, comprising:
a plurality of external terminals for an input which supply power supply potential and a control signal;
a sealing body which has a front surface and a back surface which are mutually located in an opposite side, and is arranged so that the back surface may face the external terminals for an input;
a firing element which has a main surface and a back surface which are mutually located in an opposite side, and is arranged over the front surface of the sealing body;
gunpowder arranged at the front surface side of the sealing body so that the firing element may be contacted; and
a case which stores the external terminals for an input, the sealing body, the firing element, and the gunpowder;
wherein
the sealing body has a semiconductor chip and a capacitative element, and further the sealing body has a lead frame which is a platy lead frame which has a first surface and a second surface which are mutually located in an opposite side, and has a chip mounting part which fixes the semiconductor chip, and a plurality of lead terminals arranged around the chip mounting part; and
as for the chip mounting part, the first surface is perpendicularly arranged to the main surface of the firing element.

43. An ignition device according to claim 42, wherein the sealing body has a first portion that is in contact with an inside of the case, and a second portion that is not in contact with an inside of the case; and
the first portion is located in the gunpowder side, and marking is performed to the second portion.
